(19) United States
(12) Patent Application Publication
(10) Pub. No.: US 2026/0079393 A1
(43) Pub. Date: Mar. 19, 2026

(54) SUBSTRATE PROCESSING METHOD AND SUBSTRATE PROCESSING APPARATUS

(71) Applicant: Tokyo Electron Limited, Tokyo (JP)

(72) Inventors: Kohei YAZAKI, Nirasaki City (JP); Arnaud Alain Jean DAUENDORFFER, Koshi City (JP); Kazuya DOBASHI, Nirasaki City (JP); Keisuke YOSHIDA, Nirasaki City (JP); Satoru SHIMURA, Koshi City (JP)

(73) Assignee: Tokyo Electron Limited, Tokyo (JP)

(21) Appl. No.: 19/326,837

(22) Filed: Sep. 12, 2025

(30) Foreign Application Priority Data
Sep. 13, 2024 (JP) 2024-158814
Jun. 30, 2025 (JP) 2025-110152

(51) Int. Cl. G03F 7/00; G03F 7/004; G03F 7/20; G03F 7/36

(52) U.S. Cl. CPC G03F 7/0035; G03F 7/0041; G03F 7/2004; G03F 7/2065; G03F 7/36

(57) ABSTRACT

A substrate processing method includes performing, on a substrate having a resist film formed thereon, a reduction processing of reducing hydrocarbons contained in the resist film. The resist film includes a metal oxide resist, exposed to light, and developed to have a pattern. The method further includes performing a processing of reducing roughness of the resist film after being subjected to the reduction processing.

### CROSS-REFERENCE TO RELATED APPLICATIONS

This application claims the benefit of Japanese Patent Application Nos. 2024-158814 and 2025-110152 filed on Sep. 13, 2024 and Jun. 30, 2025, respectively, the entire disclosures of each are incorporated herein by reference.

### TECHNICAL FIELD

The various aspects and embodiments described herein pertain generally to a substrate processing method and a substrate processing apparatus.

### BACKGROUND

In a manufacturing process for semiconductor devices, there is a technique of forming a wiring pattern by performing etching with a resist pattern formed by photolithography as a mask. In this photolithography, a negative type metal-containing resist is sometimes used. Patent Document 1 discloses a wafer processing apparatus equipped with a dry developing module that forms a pattern of the metal-containing resist.
Patent Document 1: International Publication No. 2024/085016

### SUMMARY

In an exemplary embodiment, a substrate processing method includes performing, on a substrate having a resist film formed thereon, a reduction processing of reducing hydrocarbons contained in the resist film, the resist film including a metal oxide resist, exposed to light, and developed to have a pattern; and performing a processing of reducing roughness of the resist film after being subjected to the reduction processing.

### BRIEF DESCRIPTION OF THE DRAWINGS

FIG. 1 is a flowchart showing a processing according to a first exemplary embodiment;

FIG. 2 is a schematic top view showing changes in a resist film as a result of the processing of FIG. 1;

FIG. 3 is a schematic top view showing changes in the resist film as a result of the processing of FIG. 1;

FIG. 4 is a schematic side view showing changes in the resist film as a result of the processing of FIG. 1;

FIG. 5 is a schematic diagram showing changes in a resist film as a result of a plasma processing;

FIG. 6 is a plan view illustrating a wafer processing system according to the first exemplary embodiment;

FIG. 7 is a front view illustrating the wafer processing system according to the first exemplary embodiment;

FIG. 8 is a longitudinal side view illustrating a plasma processing module according to the first exemplary embodiment;

FIG. 9 is a flowchart showing a processing according to a second exemplary embodiment;

FIG. 10 is a schematic diagram illustrating a reaction when a processing different from the processing according to the second exemplary embodiment is performed;

FIG. 11 is a schematic diagram illustrating a reaction when the processing according to the second exemplary embodiment is performed;

FIG. 12 is a flowchart showing a processing according to a third exemplary embodiment;

FIG. 13 is a schematic diagram showing a change in a resist film as a result of the processing according to the third exemplary embodiment;

FIG. 14 is a longitudinal side view illustrating a heating device according to a fourth exemplary embodiment;

FIG. 15 is a schematic diagram showing changes in a resist film as a result of a processing according to a fifth exemplary embodiment;

FIG. 16 is a longitudinal side view of a wafer according to a modification example;

FIG. 17 is a longitudinal side view illustrating an example where pattern collapse has occurred in the wafer according to the modification example;

FIG. 18 is a longitudinal side view illustrating a UV radiation device;

FIG. 19 provides SEM images showing a test result of Evaluation Test 1;

FIG. 20 provides SEM images showing the test result of Evaluation Test 1;

FIG. 21 is a graph showing a test result of Evaluation Test 2;

FIG. 22 is a graph showing the test result of Evaluation Test 2;

FIG. 23 is a graph showing a test result of Evaluation Test 3;

FIG. 24 is a graph showing the test result of Evaluation Test 3;

FIG. 25 is a diagram showing a test result of Evaluation Test 4;

FIG. 26 provides SEM images showing a test result of Evaluation Test 5;

FIG. 27 provides SEM images showing a test result of Evaluation Test 6;

FIG. 28 provides SEM image showing a test result of Evaluation Test 7;

FIG. 29 provides SEM images showing a test result of Evaluation Test 8;

FIG. 30 provides SEM images showing a test result of Evaluation Test 9;

FIG. 31 is a schematic diagram of an SEM image showing a lateral side of a wafer before a gas is supplied in Evaluation Test 10; and

FIG. 32 is a schematic diagram of an SEM image showing a lateral side of a part of the wafer after Evaluation Test 10.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

### First Exemplary Embodiment

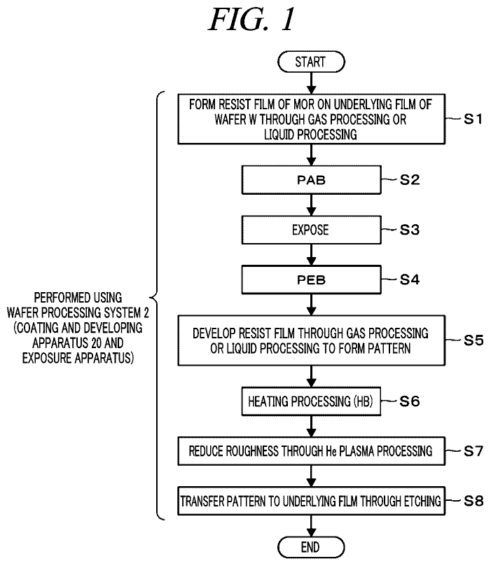

FIG. 1 shows a flow of a processing in a first exemplary embodiment. This processing involves forming a resist pattern on a wafer W as a substrate by photolithography, and then etching an underlying film 11 formed on the wafer W by using the resist pattern as a mask.

Specifically, the flow of the processing is as follows. First, a resist liquid or a deposition gas is supplied to the wafer W to form a resist film 12 made of metal oxide resist (MOR) on the underlying film 11 (process S1). This MOR is a negative type of resist containing a metal such as tin (Sn), for example, and a ligand is attached to the metal when deposition is performed. Here, “containing a metal” means that the metal is included as a constituent component, and does not mean that the metal is contained as an impurity. The ligand is composed of, for example, hydrocarbon. In the following description, unless otherwise mentioned, the resist film 12 is assumed to be a resist film composed of the MOR.

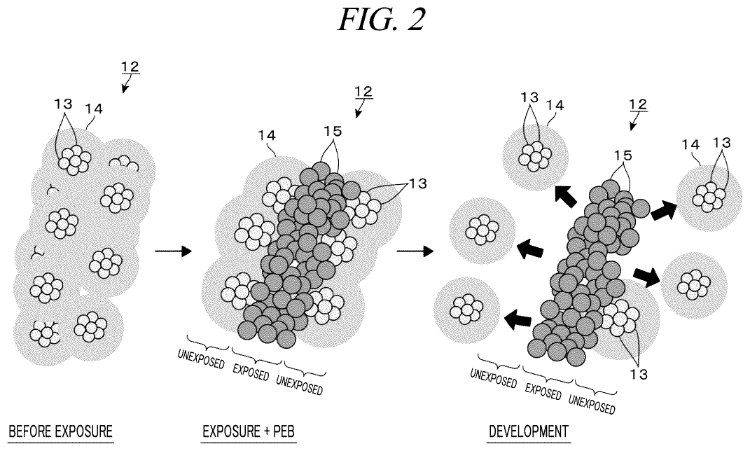

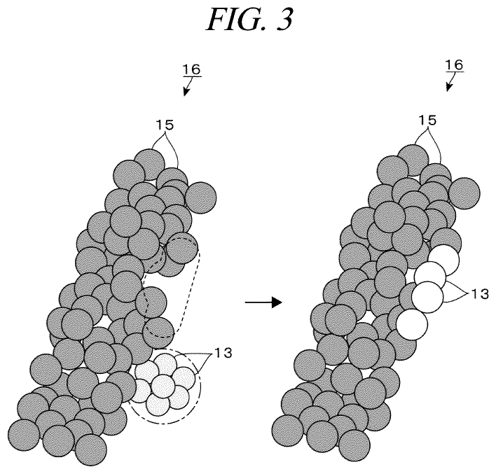

In addition to FIG. 1, reference is also made to schematic diagrams of FIG. 2 and FIG. 3. FIG. 2 and FIG. 3 are schematic diagrams illustrating a region in the resist film 12 where a linear pattern is to be formed, when viewed from above. The left side of FIG. 2 shows the resist film 12 immediately after being formed on the wafer W as a result of performing the process S1. In the figure, Sn atoms are assigned a reference numeral 13, and multiple ligands connected to the multiple Sn atoms 13 are collectively indicated by a reference numeral 14. The wafer W on which the resist film 12 is formed is then subjected to a pre-exposure heating processing (pre-applied bake (PAB)) (process S2) to volatilize and remove impurities in the film and harden the resist film 12.

After the PAB, the resist film 12 is subjected to exposure by, for example, extreme ultra violet (EUV) (process S3). The ligands 14 are released from the Sn atoms 13 at the exposed portions, and the multiple Sn atoms 13 from which the ligands 14 have been released are bonded to each other with oxygen atoms therebetween. That is, the Sn atoms 13 are oxidized to form a crosslinked structure, so that a structure of —Sn—O—Sn—O—Sn— is formed in an exposed region of the resist film 12. However, the ratio of the Sn atoms and the O atoms in the crosslinked structure is not limited to 1:1 as exemplified above.

Then, a heating processing called post exposure bake (PEB) is performed on the exposed wafer W (process S4). This PEB further promotes the release of the ligands 14 from the exposed portions and the formation of the crosslinked structures of the Sn atoms 13 via the oxygen. At the center of FIG. 2, the resist film 12 after being subjected to the PEB is illustrated, and the Sn atoms that have been oxidized to form the crosslinked structures as described above (that is, oxidized Sn) are indicated by a reference numeral 15.

Then, a developing gas or a developing liquid is supplied to the wafer W to develop the resist film 12 (process S5). As shown on the right side of FIG. 2, the Sn atoms 13, which are not the oxidized Sn 15 and still bonded with the ligands 14, are removed by this development. In other words, an unexposed region of the resist film 12, which is composed of the Sn atoms 13 bonded with the ligands 14 as described above, is removed by reacting with the developing gas or the developing liquid. FIG. 3 shows the resist film 12 upon the completion of the development, and more specifically, it illustrates a wall portion 16 of the resist pattern formed in the linear shape by the development.

Here, during the exposure of the process S3, for example, the width of the regions where the oxidized Sn 15 are formed may differ due to such a factor as unavoidable fluctuations in the output of exposure beams. Therefore, there occurs a difference in the progress of the formation of the oxidized Sn 15 at each exposed portion, which may raise a risk that irregularities may be formed on the wall portion 16 of the resist pattern. Further, on the left side of FIG. 3, the region enclosed by a dotted line is an area where the oxidized Sn 15 are supposed to be formed but no oxidized Sn 15 is actually formed due to the aforementioned non-uniformity in the exposure, resulting in a depression in the wall portion 16 of the resist pattern. Moreover, some Sn atoms 13 in a surface of the wafer W may not be removed during the development, and may form the wall portion 16 of the resist pattern together with the oxidized Sn 15. In FIG. 3, the Sn atoms 13 that have been left in this way and has become a protrusion of the wall portion 16 are indicated by a dashed dotted line. In this way, the irregularities may be formed on the wall portion 16 of the resist pattern as a result of the development not proceeding uniformly in the surface of the wafer W.

Due to the various factors stated above, roughness (surface roughness) of the wall portion 16 of the resist pattern after the development may be relatively high. If the roughness is high, there is a risk that a pattern with a required width cannot be formed when transferring the pattern by etching the underlying film 11 with this resist pattern. Therefore, in this first exemplary embodiment, after the development, a heating processing (hard bake (HB)) is performed to increase the hardness of the wall portion 16 of the resist pattern (process S6), and the resist pattern is then exposed to plasma of a helium (He) gas, which is an inert gas (process S7).

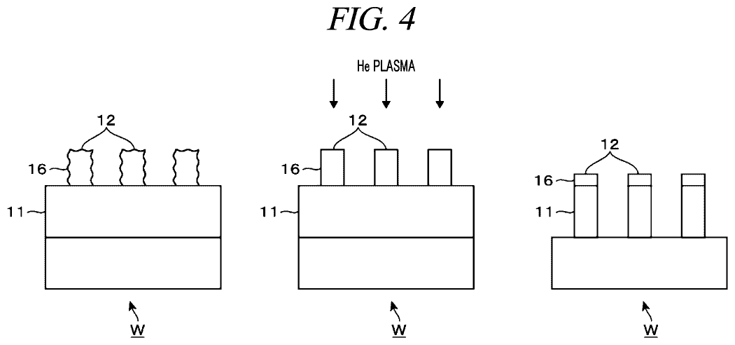

Now, reference is made to FIG. 4, which is a longitudinal side view of the wafer W. The left side of FIG. 4 shows the wafer W before being exposed to the plasma of the He gas, and the center of FIG. 4 shows the wafer W exposed to the plasma of the He gas. By exposing the wafer W to the He gas in this way, the roughness of the wall portion 16 of the resist pattern is reduced. In addition, line edge roughness (LER) (non-uniformity in a position of a line edge) and line width roughness (LWR) (non-uniformity in a line width), which are obtained by respective calculation formulas, are known as indicators of the pattern roughness. As can be seen from evaluation tests to be described later, both LER and LWR are reduced, so the roughness is reduced.

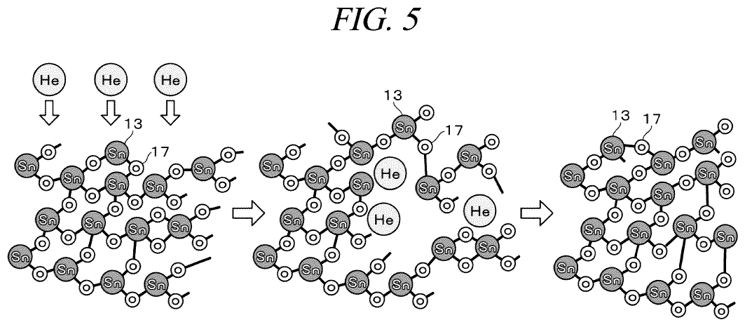

As shown in FIG. 5, the He plasma permeates the resist film 12 and breaks some of the bonds between the Sn atoms 13 and the oxygen atoms (denoted by a reference numeral 17 in the figure) that form the crosslinked structure (see the left side and the center of FIG. 5). Thereafter, when the Sn atoms 13 and the oxygen atoms 17 are recombined (see the right side of FIG. 5), it is deemed that the individual atoms are arranged with high uniformity due to an action of an intermolecular force or the like. That is, the plasma processing makes some of the Sn atoms 13 move in the resist film 12 or on the surface of the resist film 12. For example, the Sn atoms 13 having formed the protrusion of the wall portion 16 of the resist pattern as shown on the left side of FIG. 3 move to the depression of the wall portion 16 as shown on the right side of FIG. 3, resulting in the reduction of the roughness.

The underlying film 11 is etched by using the resist pattern with the reduced roughness (process S8), and the pattern is transferred to the underlying film 11 as illustrated on the right side of FIG. 4. Since the irregularities of the wall portion 16 of the resist pattern are reduced, it is possible to form a pattern with a required width in the underlying film 11 as described above. Also, as can be seen from evaluation tests to be described later, the hardness of the resist film 12 increases by being exposed to the He plasma in the process S7. Therefore, during the etching of the process S8, an opening width of the resist pattern between the wall portions 16 is difficult to widen. This also enables the pattern having the required width to be formed in the underlying film 11.

Besides the plasma of the He gas, plasma of a nitrogen (N₂) gas or argon (Ar) gas may be used as the plasma of the inert gas. However, since the molecular weights of these gases are high, there is a risk that when molecules in a plasma state collide with the resist film 12, the resist film 12 may be significantly etched. Therefore, in the aspect of suppressing a reduction in the film thickness of the resist film 12, it is desirable to use the plasma of the He gas, which has a lower molecular weight than the molecular weights of N₂ or Ar.

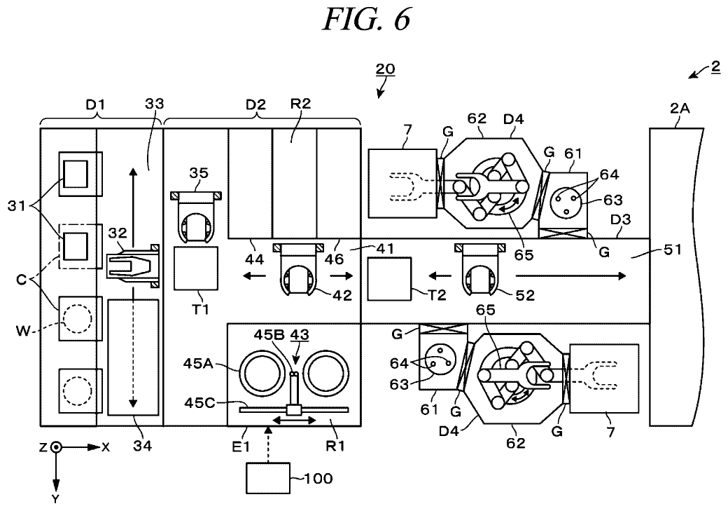

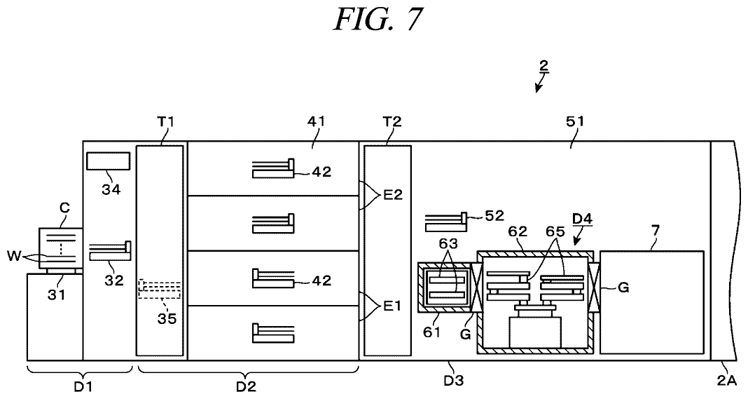

Now, an example of a wafer processing system 2 capable of performing the processes S1 to S7 in the flow described in FIG. 1 will be explained with reference to a plan view of FIG. 6 and a front view of FIG. 7. This wafer processing system 2 is prepared by connecting a coating and developing apparatus 20, which is configured to perform the processes S1 to S7 except for S3, to an exposure apparatus 2A, which is configured to perform the process S3. In describing the coating and developing apparatus 20, a left-and-right direction is defined as an X direction, and a forward-and-backward direction perpendicular to the X direction is defined as a Y direction. The coating and developing apparatus 20 includes a carrier block D1, a processing block D2, and an atmospheric transfer block D3 arranged from the left side (−X side) toward the right side (+X side), and the exposure apparatus 2A is connected to the right side of the atmospheric transfer block D3. Vacuum blocks D4 are respectively connected to the rear side (−Y side) and the front side (+Y side) of the atmospheric transfer block D3. The inside of each of the carrier block D1, the processing block D2, and the atmospheric transfer block D3 is set to be under an atmospheric pressure or an approximately atmospheric pressure.

The carrier block D1 is equipped with a multiple number of carrier stages 31 arranged in the forward-and-backward direction, and a transfer mechanism 32 configured to carry the wafer W to/from a carrier C placed on each stage 31. The carrier C is, for example, a transfer container, called a front opening unity pod (FOUP), capable of accommodating a plurality of wafers W. A transfer section 33 is formed to extend in the forward-and-backward direction when viewed from the top so that the transfer mechanism 32 can access the carrier C on each stage 31, and the transfer mechanism 32 is moved in the transfer section 33. In the transfer section 33, an inspection module 34 is provided at a height different from the position where the transfer mechanism 32 accesses the carrier C, and the transfer mechanism 32 can also access this inspection module 34. The inspection module 34 images the wafer W with, for example, a camera, before the wafer W is returned back to the carrier C after being finished with the processing of the process S7, and transmits the obtained image data to a controller 100 to be described later. Based on this image data, the controller 100 determines whether or not there is any abnormality in the resist pattern.

The processing block D2 is configured to have multiple stacked layers, each of which has a section R1 where a liquid processing module is installed and a section R2 where a non-liquid processing module is installed. The liquid processing section R1 and the non-liquid processing section R2 are arranged on the front side and the rear side of a transfer section 41, respectively, which extends in the left-and-right direction. A transfer mechanism 42 is provided in the transfer section 41.

The multiple layers include a level E1 for formation of the resist film 12 and a level E2 for development. In the shown example, two levels E2 are stacked on top of two levels E1. The level E1 for the formation of the resist film 12 is equipped with resist film forming modules 43 and 44 in the sections R1 and R2, respectively. The resist film forming module 44 for performing a gas processing is equipped with, similar to a plasma processing module 7 to be described later, a processing vessel that is configured to evacuate its interior and introduce a gas to process the wafer W. A heating module 46 for performing PAB is provided in the section R2 of the level E1. The heating module 46 is equipped with a hot plate on which the wafer W is placed and heated. An example configuration of this heating module 46 is the same as that of a heating module 46a of a fourth exemplary embodiment to be described later.

The resist film forming module 43, which is configured to perform a liquid processing, includes a cup 45A, a movable nozzle 45B configured to supply various types of liquids to the wafer W accommodated in the cup 45A to process the wafer W, and a moving mechanism 45C configured to move the nozzle 45B. The various types of chemical liquids include a solvent for resist in addition to a resist liquid. This solvent is a chemical liquid that can dissolve the resist film 12 already formed and remove it from the wafer W to re-form the resist film 12 as will be described later. The resist film forming module 43 corresponds to an integration of a film removing module that supplies the solvent to remove the resist film and a resist film forming module that supplies the resist liquid to form the resist film.

As long as the resist film can be formed at any location in the level E1, the resist film forming module 43 for liquid processing may be configured as a film removing module that supplies only the solvent among the resist and the solvent. In this case, the resist film may be formed in the resist film forming module 44, so the resist film forming module and the film removing module may be configured as separate modules. That is, there may be adopted a configuration in which the wafer W is transferred between the resist film forming module and the film removing module by a transfer mechanism. In addition, if the resist film forming module 43 can supply the resist, the resist film forming module 44 for gas processing may not be provided.

The level E2 for development is equipped with developing modules 47 and 48 in the sections R1 and R2, respectively. The developing module 47 for liquid processing and the developing module 48 for gas processing have the same configuration as the resist film forming module 43 and the resist film forming module 44, except whether they use a liquid or a gas. Further, as long as the development can be performed at any location in the level E2, only one of these developing modules 47 and 48 may be provided in the level E2. In addition, a heating module 49 for PEB and a heating module 40 for HB are provided in the section R2, and these heating modules 49 and 40 have the same configuration as the heating module 46 for PAB.

At a left end of the transfer section 41, a tower T1 is provided spanning from the lowermost level to the uppermost level, and multiple temporary placement modules (not shown) respectively capable of storing wafers W temporarily are stacked in the tower T1. A vertically movable transfer mechanism 35 is provided at the rear of the tower T1, and the transfer mechanism 35 can transfer the wafers W between the temporary placement modules. The transfer mechanism 32 of the carrier block D1 and each transfer mechanism 42 of the processing block D2 can access the tower T1, and the wafers W can be transferred between the levels E1 and E2 and the carrier block D1 via the temporary placement modules and the transfer mechanism 35. Although the transfer mechanism 42 is shown to be provided on each level, it may be shared among the multiple levels. That is, the transfer sections 41 of the multiple levels may be configured to communicate with each other.

The atmospheric transfer block D3 has a transfer section 51 extending in the left-and-right direction, and the transfer section 51 is provided with a transfer mechanism 52. Each of the transfer mechanisms 32, 35, 42, and 52 mentioned so far includes a base that is pivotable around a vertical axis and movable up and down, and a support for the wafer W that is moved back and forth on the base. Each of the transfer mechanisms 32, 42, and 52 is connected to a moving mechanism that moves the base along the transfer section. At a left end of the transfer section 51, a tower T2 configured in the same way as the tower T1 is provided, and the wafers W can be transferred between the respective levels of the processing block D2 and the transfer mechanism 52 via temporary placement module of the tower T2. The transfer mechanism 52 also accesses, in addition to the tower T2, a load lock module (LLM) 61 of each vacuum block D4 to be described later and an exposure apparatus 2A to transfer the wafers W.

Each vacuum block D4 is equipped with the LLM 61 whose internal pressure is variable, a vacuum transfer module 62 whose inside is set into a vacuum pressure, and the plasma processing module 7 whose inside is set into a vacuum pressure, and these modules are arranged in this order in the left-and-right direction. In the present exemplary embodiment, the arrangement of these modules in the left-and-right direction is reversed in the vacuum block D4 on the front side and the vacuum block D4 on the rear side. Each LLM 61 is connected to the atmospheric transfer block D3 via a gate valve G. In addition, gate valves G are also provided between the LLM 61 and the atmospheric transfer module 62, and between the atmospheric transfer module 62 and the plasma processing module 7.

Each gate valve G is opened only when necessary for the transfer of the wafers W between the modules. The internal pressure of the LLM 61 is switched between an atmospheric pressure and a vacuum pressure with the respective gate valves G connected thereto closed. The transfer of the wafers W between the LLM 61 and the atmospheric transfer block D3 is performed in the state that the LLM 61 is under the atmospheric pressure, and the transfer of the wafers W between the LLM 61 and the vacuum transfer module 62 is performed in the state that the LLM 61 is under the vacuum pressure. The LLM 61 has therein stages 63 each for placing the wafer W thereon, and these stages 63 are arranged in multiple levels, for example, in two levels. Each stage 63 has vertically movable pins 64 for the delivery of the wafer W. The atmospheric transfer module 62 is equipped with a transfer mechanism 65, which is a multi-joint arm, and serves to transfer the wafer W between the stage 63 and the stage 73 of the plasma processing module 7.

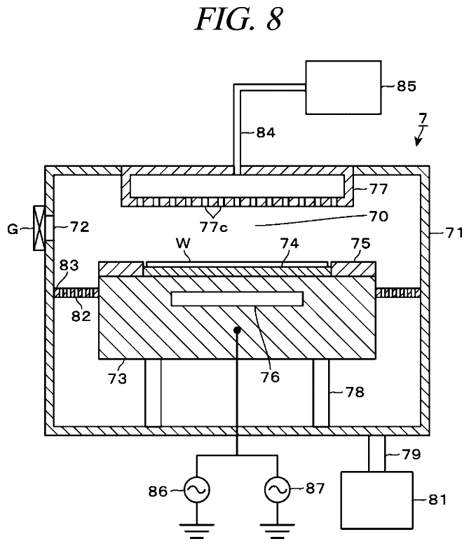

Now, the plasma processing module 7 will be explained with reference to a longitudinal side view of FIG. 8. The plasma processing module 7 is equipped with a processing vessel 71. A reference numeral 72 in the figure represents a transfer port provided in a sidewall of the processing vessel 71. A stage 73 for placing the wafer W thereon is provided in the processing vessel 71. An upper central portion of the stage 73 is configured as an electrostatic chuck 74, to which a rear surface of the wafer W is attracted during a plasma processing. A focus ring 75 is provided on an upper periphery of the stage 73, surrounding the wafer W on the electrostatic chuck 74, to adjust a distribution of plasma formed in a processing space 70 above the wafer W.

A temperature adjuster 76 is embedded in the stage 73 to adjust the temperature of the wafer W on the electrostatic chuck 74. The temperature adjuster 76 is implemented by a flow path into which a fluid whose temperature has been adjusted by, for example, a heater or a chiller is supplied. In addition, like the pins 64 of the LLM 61, the stage 73 is provided with pins configured to be protruded from and retracted below a wafer placement surface (a top surface of the electrostatic chuck 74) of the stage 73 to transfer the wafer W between the transfer mechanism 65 and the stage 73, but illustration of these pins is omitted in FIG. 8.

A reference numeral 78 in FIG. 8 represents a support column that supports the stage 73 in the processing vessel 71. A reference numeral 79 in FIG. 8 is an exhaust pipe, whose upstream end is open to a bottom of the processing vessel 71 and whose downstream end is connected to an exhaust mechanism 81 composed of a turbomolecular pump, a dry pump, or the like. The processing vessel 71 is evacuated into a vacuum atmosphere of a required pressure level by the exhaust mechanism 81. In order to improve the uniformity of the evacuation at individual portions along the circumference of the stage 73, a baffle plate 83 having a multiple number of through holes 82 bored in a thickness direction is provided, and this baffle plate 83 surrounds the stage 73 and partitions the processing vessel 71 into upper and lower portions.

A downstream end of a gas supply pipe 84 is connected to a ceiling portion of the processing vessel 71, and a discharge port 77c is formed in the ceiling portion. In the present exemplary embodiment, a shower head 77 having a gas diffusion space and connected to the downstream end of the gas supply pipe 84 is provided at the ceiling portion of the processing vessel 71. A plurality of the discharge ports 77c is formed in a bottom of the shower head 77 to allow a gas diffusion space and the processing space 70 to communicate with each other. As another example of the present exemplary embodiment, a nozzle may be provided at the ceiling portion of the processing vessel 71, and the downstream end of the gas supply pipe 84 may be connected to this nozzle, and one discharge port 77c, for example, may be formed at this nozzle. A processing gas supplied via the gas supply pipe 84 from a gas supply mechanism 85 provided upstream of the gas supply pipe 84 is discharged into the processing space 70 from the discharge ports 77c formed in the ceiling portion after being supplied. This processing gas is the aforementioned He gas.

In the plasma processing module 7, the ceiling portion (the shower head 77 in the present exemplary embodiment) of the processing vessel 71 serves as an upper electrode, and the stage 73 serves as a lower electrode to form capacitively coupled plasma. Radio frequency (RF) powers of different frequencies are applied to the stage 73 from a first RF power supply 86 and a second RF power supply 87. The first RF power supply 86 supplies an RF power of a low frequency (LF) of, e.g., 13 MHz, to the stage 73. The second RF power supply 87 supplies an RF power of a high frequency (HF) of, e.g., 100 MHz, which is higher than that of the RF power from the first RF power supply 86, to the stage 73. By supplying the RF power from either the first RF power supply 86 or the second RF power supply 87, an electric field is formed in the processing space 70 to excite the processing gas into plasma. The RF powers from both the first and second RF power supplies 86 and 87 may be supplied. In such a case, the second RF power supply 87 is used as an RF power supply for plasma formation, and the first RF power supply 86 is used as an RF power supply for bias application to attract ions included in the plasma toward the stage 73. As will be described later in evaluation tests, when the RF power is supplied only from the second RF power supply 87 in the first and second RF power supplies 86 and 87, it is desirable that this RF power is in the range of, e.g., 100 W to 1000 W, inclusive, in this first exemplary embodiment. In the plasma processing module 7 of the present exemplary embodiment, at least one of the first and second RF power supplies 86 and 87 and the upper and lower electrodes mentioned above correspond to a plasma forming mechanism.

A processing sequence of the wafer W in the plasma processing module 7 will be explained as follows. The wafer W carried into the processing vessel 71 set into a preset vacuum pressure is placed on the electrostatic chuck 74. The processing gas is then supplied into the processing space 70, and the power is supplied to the stage 73 from the first RF power supply 86 and/or the second RF power supply 87. As a result, the processing gas is excited into plasma, and the wafer W is exposed to the plasma. Thereafter, the supply of the processing gas is stopped, and the power supply from the first RF power supply 86 and/or the second RF power supply 87 is stopped, thereby completing the processing. The wafer W is then carried out from the processing vessel 71.

Referring back to FIG. 6, the coating and developing apparatus 20 constituting the wafer processing system 2 is equipped with a controller 100. The controller 100 is implemented by a computer, and includes a program and circuitry such as a memory (non-transitory computer-readable media) and a central processing unit (CPU). Of course, one of ordinary skill will recognize that the computer circuitry may be implemented in a field programmable gate array (FPGA) circuit, application specific integrated circuit (ASIC), or other hardware circuitry. Thus, the circuitry including a memory and CPU is merely exemplary and not limiting upon the present disclosure. The program includes process groups that allow a series of operations in the coating and developing apparatus 20 to be described later to be performed. The controller 100 outputs control signals to the individual components of the coating and developing apparatus 20 according to the program, and as the operations of the individual transfer mechanisms and the individual modules are controlled in response to the control signal, the transfer of the wafer W and the processing of the wafer W in the respective modules are carried out. The program is stored in a non-transitory recording medium such as a compact disk, a hard disk, or a DVD, and is installed into the controller 100.

Now, the processing sequence of the wafer W and a transfer path of the wafer W in the wafer processing system 2 will be explained in association with the flow in FIG. 1. The wafer W in the carrier C is transferred to the resist film forming module 43 or 44 on the level E1 of the processing block D2 and then to the heating module 46 for PAB to be subjected to the processing of the processes S1 and S2. The wafer W is then transferred to the exposure apparatus 2A via the atmospheric transfer block D3, where the exposure of the process S3 is performed on the wafer W. Subsequently, the wafer W is transferred to the level E2 of the processing block D2 via the atmospheric transfer block D3, and transferred in sequence to the heating module 49 for PEB, the developing module 47 or 48, and the heating module 40 for HB to be subjected to the processing of the processes S4 to S6.

Then, the wafer W is returned to the atmospheric transfer block D3, and then transferred to the plasma processing module 7 via the LLM 61 and the vacuum transfer module 62 of the vacuum block D4 in sequence. In the plasma processing module 7, the wafer W is placed on the stage 73, and the process S7 is performed. Thereafter, the wafer W is returned to the atmospheric transfer block D3 along a path reverse to that taken to carry the wafer W into the plasma processing module 7, and is then returned back to the carrier block D1 through one of the levels of the processing block D2. Then, the wafer W is transferred to the inspection module 34, where it is imaged, and is then returned back into the carrier C. The controller 100 makes a determination on whether there is any abnormality in the resist pattern formed on the wafer W based on the obtained image data. As a specific example, a determination is made as to whether or not LER and LWR are below threshold values. Then, the carrier C into which the wafer W having the resist pattern formed thereon has been returned is transferred to an etching apparatus, where the etching of the process S8 is performed on the wafer W.

According to the wafer processing system 2 in the first exemplary embodiment described above, the wafer W is transferred to the plasma processing module 7 after the developing processing, and the resist pattern is exposed to the plasma of the He gas, thereby improving the LER and the LEW and enhancing pattern strength, as can be seen from test results to be described later.

However, the wafer W that is determined by the controller 100 to have the abnormality in the resist pattern based on the image data of the inspection module 34 is transferred again to the resist film forming module 43 on the level E1 of the processing block D2 after or before being returned to the carrier C, for example. Then, the solvent is supplied to the wafer W re-transferred to the resist film forming module 43 to remove the resist film 12 (i.e., the resist pattern) of the wafer W, and the resist film 12 is formed again on the wafer W by the resist film forming modules 43 and 44. In this way, before the wafer W is transferred from the wafer processing system 2 to another system or apparatus along with the transfer of the carrier C, the resist film 12 is formed again on the wafer W in the wafer processing system 2. The wafer W on which the resist film 12 has been re-formed is then transferred to and processed by the series of modules described above, so that the resist pattern is formed again.

As described above, according to the wafer processing system 2 of the present disclosure, instead of discarding a wafer W found to have an abnormal resist pattern, re-formation and inspection of the resist pattern may be repeatedly performed until the resist pattern is determined to have no abnormality. By re-forming the resist pattern in this manner, it is possible to suppress occurrence of an etching defect due to a defect in the resist pattern.

The inspection of the resist pattern (determination of the presence or absence of the abnormality) is not limited to being performed in the inspection module 34, but may be performed by returning the wafer W to the carrier C and transferring the carrier C to an inspection apparatus. Then, when forming the resist pattern again on the wafer W that has been determined to have the abnormality in the inspection by the inspection apparatus, the carrier C may be transferred again to the wafer processing system 2.

The above exemplary embodiment has been described for the wafer processing system 2 capable of performing the formation of the resist pattern in the processes S1 to S7 and the removal of the resist film for the re-formation of the resist pattern. However, the exemplary embodiment is not limited to using this wafer processing system 2, and the system configuration (apparatus configuration) may be modified appropriately. The individual processes of performing the formation and the re-formation of the resist pattern may be carried out by transferring the carrier C between multiple substrate processing apparatuses each of which is equipped with at least one of the various modules for resist film removal, resist film formation, heating (PAB, PEB, HB), exposure, and development, and these substrate processing apparatuses may be configured as a system for performing the processes S1 to S7. That is, the system is not limited to the configuration in which the formation of the resist pattern is performed during a period from when the wafer W is taken out from the carrier C until it is returned back into this carrier C.

Further, the wafer processing system 2 may also be configured to perform the etching processing of the process S8. Thus, the system may be configured to perform the processing of the processes S1 to S8 on the wafer W during the period from when the wafer W is taken out from the carrier C until it is returned back into the carrier C. To specifically describe this example system configuration, in the above-described wafer processing system 2, one of the two plasma processing modules 7 is changed to an etching module. This etching module may have the same configuration as the plasma processing module 7, except that, for example, the gas supply mechanism 85 supplies an etching gas corresponding to the material of the underlying film 11 formed on the wafer W into the processing space 70. The underlying film 11 is etched in a vacuum atmosphere by the etching gas. Here, depending on the material of the underlying film or the type of the etching gas, etching may be performed without forming plasma in the processing space 70.

### Second Exemplary Embodiment

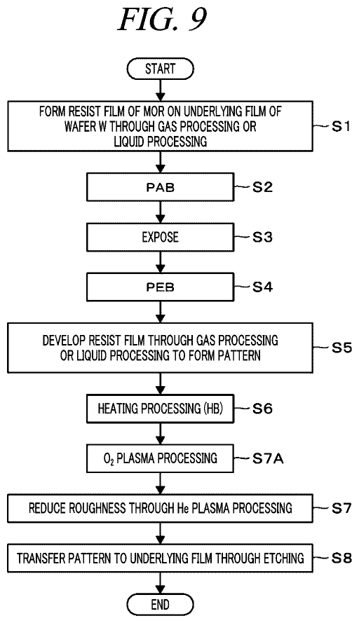

Now, a second exemplary embodiment will be described, focusing on distinctive features from the first exemplary embodiment. FIG. 9 shows a flowchart of a processing in the second exemplary embodiment. After forming the resist pattern by the development and before performing the He plasma processing of the process S7, a processing of exposing the resist pattern to plasma of O₂ (oxygen) gas is performed as a process S7A. Further, although the process S7A is shown in the figure as being performed after the heating processing of the process S6, the heating processing of the process S6 may not be performed. By performing this process S7A, both LER and LWR are reduced, and the roughness is reduced, as can be seen from the evaluation tests to be described later.

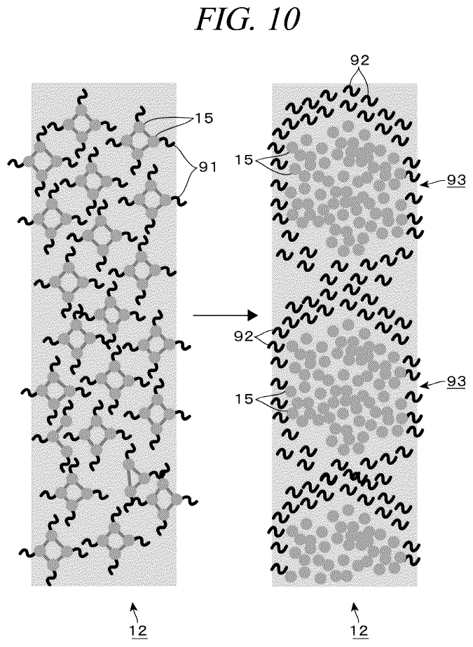

In order to show the effect of carrying out the above-described process S7A, a reaction that is assumed to take place in the resist film 12 forming the resist pattern when the processing is performed according to the flowchart of FIG. 9 without performing the process S7A will be explained with reference to FIG. 10. The left side of FIG. 10 illustrates a state before the exposure to the He plasma (a state before carrying out the process S7), and the right side of FIG. 10 illustrates a state after the exposure to the He plasma (a state after carrying out the process S7).

As described in the first exemplary embodiment, the Sn atoms are crosslinked via the oxygen and constitute the oxidized Sn 15, but as shown on the left side of FIG. 10, some of the Sn atoms forming the oxidized Sn 15 are coordinated with ligands 91 composed of hydrocarbon. This coordination bond is broken by the action of the He plasma, and the ligands 91 become molecules 92 of a hydrocarbon compound to be separated from the Sn atoms. Metal particles tend to be relatively easily separated by carbon. Therefore, the molecules 92 of the hydrocarbon compound act as a grain boundary material of the oxidized Sn 15, causing migration of particles 93 of the oxidized Sn 15. Specifically, as shown on the right side of FIG. 10, the molecules 92 surround the particles 93 formed by the aggregation of the molecules of the oxidized Sn 15, suppressing the particles 93 from coming into contact with and bonded with each other. This suppresses the particles 93 from being densely arranged in the film, which is deemed to cause the roughness.

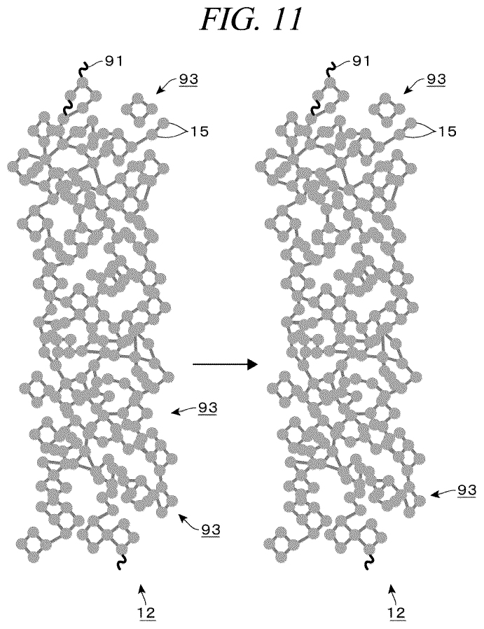

As a resolution, by performing the process S7A, the bonds between the Sn atoms and the ligands 91 of the hydrocarbon are broken, and the ligands 91 (the molecules 92 of the hydrocarbon compound) are ashed. The left side of FIG. 11 shows the resist film 12 after being subjected to this ashing, and the right side of FIG. 11 illustrates the resist film 12 after being processed by the He plasma in the process S7 after the ashing. Since most of the ligands 91 are removed by the ashing of the process S7A, generation of the molecules 92 of the hydrocarbon compound is suppressed in the process S7 after the ashing. As a result, occurrence of the migration of the particles 93 of the oxidized Sn 15 described in FIG. 10 is suppressed, so the particles 93 are closely arranged by coming into contact with and being bonded with each other, thereby suppressing the roughness.

If the processing flow of FIG. 9 is performed by using the wafer processing system 2 as in the first exemplary embodiment, the process S7A may be performed by using the plasma processing module 7. When performing the process S7A, the gas supply mechanism 85 of the plasma processing module 7 is configured to supply the O₂ gas as well. Processing conditions such as the temperature of the wafer W and the pressure in the processing space 70 during the formation of the O₂ plasma and formation of the He plasma may be the same or different. As will be described later as the evaluation test, when the He plasma processing is performed by supplying the RF power only from the first RF power supply 86 in the first RF power supply 86 and the second RF power supply 87 in this second exemplary embodiment, the RF power is desirably set to a value higher than, for example, 1000 W. Since the wafer processing system 2 is provided with the two plasma processing modules 7, the O₂ plasma processing in the process S7A and the He plasma processing in the process S7 may be performed in the separate plasma processing modules 7.

In performing the process S7A, the plasma of the O₂ gas is used as plasma of an oxidizing gas, but the oxidizing gas is not limited to the O₂ gas, as long as the hydrocarbon can be removed by the ashing. By way of example, an oxidizing gas composed of oxygen atoms, such as an ozone gas, a nitric oxide or a nitrogen dioxide, may be used instead of the O₂ gas to generate plasma and perform the process S7A.

Here, any aspects described in the first exemplary embodiment that are applicable to the second exemplary embodiment may be appropriately applied. Therefore, in the second exemplary embodiment, the resist pattern may be re-formed based on the inspection, or the individual processes in the processing flow of FIG. 9 may be performed sequentially by transferring the carrier C between the apparatuses. Also, in various exemplary embodiments to be described below, any aspects described up to that point that are applicable may be appropriately applied.

### Third Exemplary Embodiment

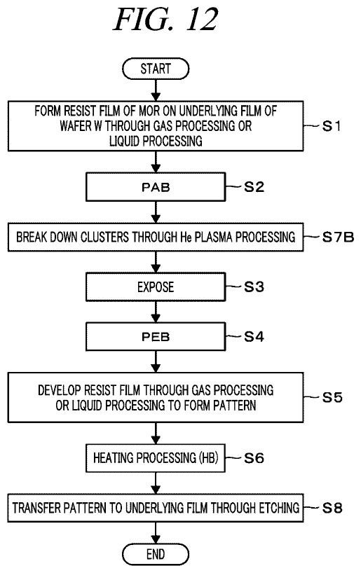

FIG. 12 shows a flow of a processing according to a third exemplary embodiment. In this processing flow, after the PAB in the process S2, a process S7B in which the resist film 12 is exposed to plasma of an inert gas is performed before performing the exposure of the process S3. Plasma of a He gas, for example, may be used as the plasma of the inert gas, the same as in the first exemplary embodiment.

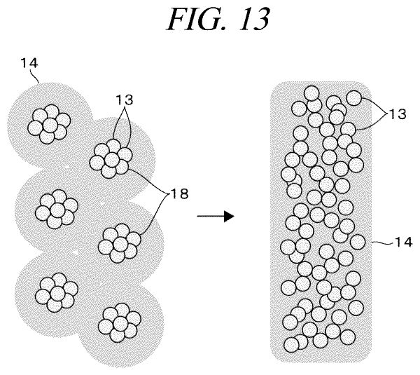

FIG. 13 is a schematic diagram showing a change in the resist film before and after the plasma processing with the inert gas. As shown on the left side of FIG. 13, before the plasma processing, a multiple number of Sn atoms 13 aggregate to form clusters 18, and there is a bias in the distribution (stochastics) of the Sn atoms 13 in the resist film 12. Therefore, since there are regions in the resist film where the content of the Sn atoms 13 is relatively small, if exposure and development are performed without performing the plasma processing of the process S7B, there is a risk that a crack may occur in the wall portion 16 of the resist pattern formed by the development. Furthermore, the crack may cause an unintended break in the linear wall portion 16, which is called pinching. Furthermore, since the Sn atoms 13 are densely distributed because of the formation of the clusters 18, if the exposure and the development are performed without carrying out the plasma processing of the process S7B, minute protrusions caused by the shape of the clusters 18 may be formed on the surface of the wall portion 16 of the resist pattern, resulting in deterioration of the roughness.

In order to suppress these problems, according to the third exemplary embodiment, the resist film 12 before being subjected to the exposure for forming the resist pattern is exposed to the plasma of the inert gas in the process S7B as stated above. This breaks down the clusters 18 and disperses the Sn atoms 13, improving the uniformity in the distribution of the Sn atoms 13 (as shown on the right side of FIG. 13). Then, the resist film 12 is subjected to the above-described processing (processes S3 to S6, and S8) from the exposure onward, thereby reducing the roughness of the resist pattern and suppressing the occurrence of chipping or the formation of minute protrusions on the wall portion 16 forming the resist pattern.

In the flow of FIG. 12, the resist film 12 is exposed to the He gas plasma after the PAB of the process S2. However, the resist film 12 may be exposed to the He gas plasma after the resist film 12 is formed in a process S1 and before it is subjected to the PAB in the process S2. Therefore, after the resist film 12 is formed on the wafer W, the plasma processing with the inert gas may be performed before the Sn crosslinked structure (oxidized Sn 15) is formed through the exposure of the process S3.

Even in the case where the resist film 12 is plasma-processed before the exposure as described above, the resist film 12 after being subjected to the pattern formation may also be plasma-processed as stated in the first and second exemplary embodiments. That is, the third exemplary embodiment may be combined with the first or second exemplary embodiment described above. Further, the expression “before the exposure” in the description of the third exemplary embodiment means “before the exposure that is performed prior to the pattern formation on the resist film through the development”. Thus, the plasma processing with the inert gas according to the third exemplary embodiment may be performed after performing exposure to remove an unnecessary resist film on a peripheral portion of the wafer W, for example.

### Fourth Exemplary Embodiment

A flow of a processing in a fourth exemplary embodiment is the same as that in the first exemplary embodiment. PAB in the process S2 in this flow is performed by setting the vicinity of the wafer W into a vacuum atmosphere and an inert gas atmosphere. The reason for this will be explained below. By carrying out the PAB in the vacuum atmosphere, impurities that are included in the resist film 12 but are not necessary for pattern formation are more readily released from the resist pattern 12. If the impurities are thus removed, substances remaining in the resist film 12 that are necessary for pattern formation, such as the Sn atoms 13, are dispersed so that they are moved to spaces in the film from which the impurities are released. As a result, their distribution becomes more uniform, which may reduce the roughness. The aforementioned impurities may be, for example, a solvent of the resist. When the resist film 12 is formed by a liquid processing (when the resist film forming module 43 configured to perform a processing with the resist is used), the solvent is contained in a relatively large quantity in the film, so in this case, it is particularly effective to carry out the PAB in the vacuum atmosphere.

In addition, as oxygen acts on the wafer W having thereon the resist film 12 before being exposed, the Sn atoms 13 still coordinated with the ligands 14 form a crosslinked structure via oxygen atoms. At this time, the ligands 14 cause steric hindrance, making it difficult for the Sn atoms 13 to be densely arranged. As a result, the molecular structure constituting the crosslinked structure becomes relatively distorted. After development, this distorted molecular structure appears as irregularities on the wall portion 16 of the resist pattern, resulting in an increase of pattern roughness. In order to suppress the unintended reactions between the Sn atoms 13 coordinated with the ligands 14, it is desirable to shorten the time during which the wafer W is exposed to the oxygen atmosphere between the formation of the resist film and the exposure, or to set an oxygen concentration in an atmosphere around the wafer W to be relatively low. To this end, by setting the atmosphere around the wafer W during the PAB to the inert gas atmosphere, the unintended reactions during the PAB may be suppressed, so that the roughness of the resist pattern can be reduced.

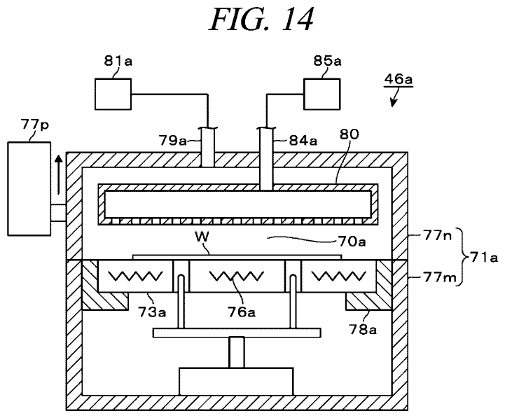

FIG. 14 is a longitudinal side view of a heating module 46a, which is a heating apparatus configured to perform the PAB of the process S2 in the fourth exemplary embodiment. In the heating module 46a shown in this figure, the same components as those in the plasma processing module 7 shown in FIG. 8 will be assigned the same reference numerals, such as a processing vessel 71a, and the following explanation will mainly focus on distinctive features from the plasma processing module 7. The processing vessel 71a is composed of a bottom vessel 77m and a top cover 77n, and a stage 73a is provided in a top opening of the bottom vessel 77m with an annular support body 78a therebetween. This stage 73a is configured as a hot plate including therein a heater 76a, for example.

The top cover 77n is configured to be moved up and down by an elevating mechanism 77p. At a lowered position, the top cover 77n covers the bottom vessel 77m, keeping the interior of the processing vessel 71a hermetically sealed. Inside the top cover 77n, there is provided a shower head 80 to which a gas supply mechanism 85a configured to supply an inert gas is connected via a gas supply pipe 84a. The inert gas is supplied into an internal space of the shower head 80, and is supplied into the processing space 70a through multiple through holes provided in a lower portion of the shower head 80. An exhaust mechanism 81a is connected via an exhaust pipe 79a to a gap between the shower head 80 and the top cover 77n, and the processing space 70a is evacuated into a vacuum atmosphere through this gap.

With the processing vessel 71a hermetically sealed, the inert gas is supplied from the shower head 80 and the evacuation by the exhaust mechanism 81a is performed to turn the inside of the processing vessel 71a into the vacuum atmosphere and the inert gas atmosphere. In this state, the wafer W placed on the stage 73a is heated and the PAB is performed. The vacuum atmosphere of the processing vessel 71a is lower than an atmospheric pressure, but it is desirable to set the vacuum atmosphere to, for example, 102 Pa or less, which is lower than or equal to a medium vacuum, so that the above-described impurities can be removed efficiently.

For the reasons stated above, it is desirable that the inside of the processing vessel 71a during the heating processing of the wafer W is under the vacuum atmosphere and the inert gas atmosphere. However, by adjusting the degree of the evacuation and the amount of the inert gas supplied, the processing vessel 71a may be set into the atmospheric pressure, like the outside of the processing vessel 71a, and the PAB may be performed on the wafer W under this atmospheric pressure. That is, between the vacuum atmosphere and the inert gas atmosphere, only the inert gas atmosphere may be formed in the processing vessel 71a to process the wafer W. Alternatively, the gas supply mechanism 85a may supply air, and between the vacuum atmosphere and the inert gas atmosphere, only the vacuum atmosphere may be formed in the processing vessel 71a to process the wafer W.

In the above description, the impurities are removed by creating the vacuum atmosphere around the wafer W when performing the PAB. However, as long as the impurities can be removed, the vacuum atmosphere may be created around the wafer W at any timing after the resist film 12 is formed on the wafer W and before the crosslinked structure of the Sn atoms 13 is formed through the exposure in the exposure apparatus 2A. As a specific example, a standby module in which the wafer W is on standby may be provided on a transfer path of the wafer W ranging from the resist film forming modules 43 and 44 to the exposure apparatus 2A in the wafer processing system 2. The standby module may include a housing, an opening/closing mechanism for opening and closing a transfer port for the wafer W provided in the housing, and a placement module configured to place the wafer W in the housing, and may be configured to form, inside the housing, an airtight space in which the wafer W is placed on standby. The standby module may be further equipped with a mechanism configured to evacuate the airtight space, so that the vacuum atmosphere can be formed around the wafer W on standby.

In addition, a mechanism configured to supply an inert gas to the transfer path from the resist film forming modules 43 and 44 to the exposure apparatus 2A may be provided to create an inert gas atmosphere in the transfer path, thereby reducing the amount of oxygen that comes into contact with the resist film 12 and the time during which the resist film 12 is exposed to the oxygen before it is exposed, so that the aforementioned unnecessary reactions may be suppressed. The inert gas that forms the inert gas atmosphere in the fourth exemplary embodiment is, by way of non-limiting example, a N₂ (nitrogen) gas, but another inert gas such as an Ar gas or a He gas may be used instead. The PAB of this fourth exemplary embodiment has been described as being applied to the first exemplary embodiment, but is not limited thereto and may also be applied to the second and third exemplary embodiments and other exemplary embodiments to be described later.

### Fifth Exemplary Embodiment

A fifth exemplary embodiment is a modification example of the first exemplary embodiment, in which the wafer W is processed according to the flow described in FIG. 1. In the fifth exemplary embodiment, the RF power supplied for plasma formation during the plasma processing with the inert gas in the process S7 is set to be relatively high to cause directed self-assembly (DSA) in the resist film 12 forming the resist pattern. This changes the shape of the resist pattern. More specifically, the aforementioned pinching is intentionally generated and used to modify the resist pattern. Plasma of the inert gas used in this fifth exemplary embodiment is, for example, plasma of a He gas, the same as in the first exemplary embodiment.

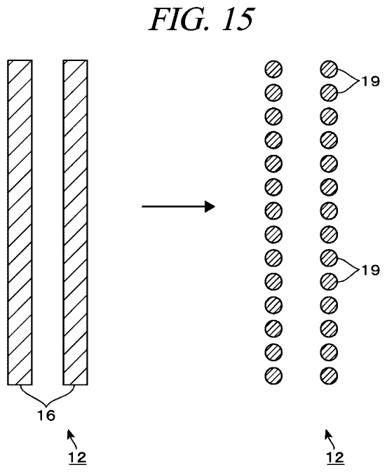

A change in the resist pattern will be specifically explained with reference to a plan view of FIG. 15. The left side of FIG. 15 shows the resist film 12 before the process S7 is performed, and the right side of FIG. 15 shows the resist film 12 after the process S7. As shown on the left side of FIG. 15, before the process S7 is performed, the wall portion 16 of the resist pattern is formed in the linear shape when viewed from the top. Due to the DSA caused by the process S7, the wall portion 16 is broken down in a longitudinal direction when viewed from the top, resulting in granulation, and a number of circular, grain-shaped wall portions 19 are formed, as shown on the right side of FIG. 15. The wall portion 16 is presumed to be broken down in this way due to the migration of the particles 93 of the oxidized Sn 15 via the molecules 92 of the hydrocarbon compound during the He plasma processing, as explained in FIG. 10. Therefore, in this fifth exemplary embodiment, the plasma processing by the oxidizing gas in the process S7A explained in the second exemplary embodiment is not performed, but the plasma processing by the He gas in the process S7 is performed.

Then, in the process S8 after changing the resist pattern in this way, the underlying film 11 is etched using the resist pattern formed of the wall portions 19. Thus, the underlying film 11 is etched in grain shapes so that wall portions are left. In the process S7 of this fifth exemplary embodiment, the RF power for plasma formation supplied to the stage 73 serving as an electrode is set to be of a value different from that in the first exemplary embodiment, and to be of a value higher than 1000 W, as can be seen from the evaluation test to be described later.

### Modification Examples

In addition, the plasma processing with the inert gas described in the exemplary embodiments other than the third exemplary embodiment may be performed before the HB by the heating module 40. Further, the HB may not be performed in each of the above-described exemplary embodiments. Also, the plasma processing with the inert gas is not limited to being performed in the plasma processing module 7, but may be performed in another module capable of forming the plasma of the inert gas, which is provided outside the wafer processing system 2. As an example of another module that forms the plasma of the inert gas, the developing module 48 for gas processing may be employed. In this case, the developing module 48 is configured to supply plasma, like the plasma processing module 7 shown in FIG. 8, and is also equipped with a gas supply mechanism configured to supply an inert gas. Thus, the developing module 48 may be configured as the plasma processing module 7, which has a configuration in which the gas supply mechanism 85 can supply both an inert gas and a developing gas into the processing space 70. The developing gas includes, by way of example, at least one of a hydrogen bromide (HBr) gas, a boron trichloride (BCl₃) gas, and an acetic acid (CH₃COOH) gas.

As described above, the exemplary embodiments are not limited to performing the HB between the developing processing and the plasma processing of the inert gas. Therefore, if the developing module 48 is configured to be capable of performing the plasma processing with the inert gas as described above, the developing processing and the plasma processing may be performed in sequence in the developing module 48 in the exemplary embodiments other than the third exemplary embodiment. That is, the developing processing and the plasma processing of the inert gas may be performed in sequence on the wafer W in the same processing vessel 71. Further, when performing the second exemplary embodiment in this developing module 48, there may be adopted a configuration in which an oxidizing gas such as an oxygen gas can also be supplied from the gas supply mechanism 85 of the developing module 48, and the developing processing, the plasma processing by the oxidizing gas, and the plasma processing by the inert gas may be performed in this order in the same processing vessel 71. That is, the processes S5, S7A, and S7 in the flow of FIG. 9 may be performed in sequence in the same processing vessel 71.

When performing the developing processing in this developing module 48, the processing space 70 is set to a predetermined pressure, and the developing processing is performed by supplying the developing gas to the wafer W placed on the stage 73 and adjusted to a preset temperature. The temperature of the wafer W and the pressure of the processing space 70 in the developing processing may be changed appropriately from the temperature and the pressure set in the plasma processing. The pressure is not limited to the vacuum pressure, and may be set to the atmospheric pressure. In addition, plasma may be formed in the processing space 70 during the developing processing, but the processing may be performed without forming the plasma, for example.

When the developing module 48 is configured to be able to perform the plasma processing with the inert gas, the plasma processing module 7 need not be provided, and the plasma processing with the inert gas may be performed in the developing module 48. In addition, since the plasma processing can be performed following the developing processing in one and the same processing vessel, the time required for transferring the wafer W between the modules is reduced, so that the throughput of the system that performs the processing flow of each exemplary embodiment can be improved.

The plasma processing module 7 is configured to process the wafer W by forming capacitively coupled plasma. However, the module configuration is not limited to processing the wafer W by using capacitively coupled plasma. For example, the module may be configured to process the wafer W by forming inductively coupled plasma in the processing space 70, or to process the wafer W by plasma formed by radiating a microwave into the processing space 70. The plasma is not limited to being formed inside the processing vessel, and the module may adopt a configuration of performing a so-called remote plasma processing, in which the plasma is formed in a flow path connected to the processing vessel and then introduced into the processing vessel to process the wafer W.

In addition, the electrode to which the RF power of 100 MHz is applied from the second RF power supply 87 in the plasma processing module 7 is shown to be provided in the stage 73, but its location is not limited thereto. The power from the second RF power supply 87 may be supplied to an electrode at the ceiling of the processing vessel 71 to form capacitively coupled plasma.

As stated above, through the exposure in the process S3, the hydrocarbons, which are ligands coordinated with Sn atoms, are removed, so that Sn bonding via oxygen is facilitated. However, at an exposed portion of the resist film 12, some of the hydrocarbons remain bonded to Sn. As described above, in the second exemplary embodiment, in the process S7A, the ashing is performed by exposing the resist film 12 of the wafer W to the O₂ plasma, so that the hydrocarbons still bonded to the Sn atoms after the exposure are removed. That is, by exposing the wafer W to the O₂ plasma, a processing of reducing the concentration of the hydrocarbons in the resist film 12 is performed. This promotes the formation of Sn bonds via oxygen, and hardens the exposed portion, i.e., the resist pattern. Also, occurrence of the migration due to the molecules 92 of the hydrocarbon compound is suppressed, so that the roughness of the resist pattern is reduced.

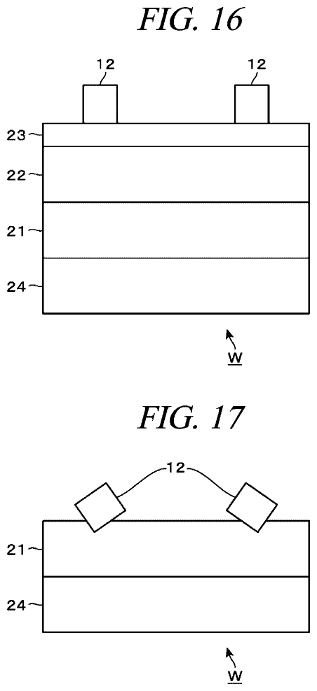

Now, reference is made to FIG. 16, which is a longitudinal side view of the wafer W. In this wafer W, a SiO₂ film 21 made of tetraethoxysilane (TEOS), an organic dielectric layer (ODL) film 22 which is an insulating film made of an organic material, and an underlying film 23 are stacked upwards in this order on a film 24, and the resist film 12 is formed on the underlying film 23. The underlying film 23 may be a film (inorganic film) made of an inorganic material such as spin-on glass (SOG) mainly composed of Si. In this case, the ODL film 22 is less likely to be affected by the above-described oxygen plasma processing. However, the underlying film 23 may be made of a material mainly composed of an organic matter, that is, an organic film containing carbon. Here, containing carbon does not mean that carbon is contained as an impurity, but means that it is contained as a main component. One specific example of such an organic film is an amorphous carbon film.

When the underlying film 23 is an organic film, the amount of ashing of the underlying film 23 may become relatively large during the O₂ plasma processing in the process S7A of the second exemplary embodiment, depending on processing conditions, and there is a risk that the wall portion constituting the resist pattern may collapse, that is, pattern collapse may occur. FIG. 17 illustrates an example in which the ODL film 22 as well as the underlying film 23 is ashed, causing the pattern collapse. Therefore, the processing conditions of the second exemplary embodiment are set to suppress such excessive ashing. The processing conditions will be explained later in the evaluation test.

In the second exemplary embodiment, instead of performing the ashing with the O₂ plasma in the process S7A, an oxidizing gas not excited into plasma may be supplied to the wafer W placed in the processing vessel 71 to remove the hydrocarbons as the ligands for Sn from the resist pattern, i.e., to reduce the concentration of the hydrocarbons in the resist film 12. Here, when supplying this oxidizing gas, the processing vessel 71, for example, is decompressed. That is, the hydrocarbon concentration reducing processing is performed by forming a vacuum atmosphere inside the processing vessel 71 and supplying a non-plasma oxidizing gas into the processing vessel 71.

The oxidizing gas may be any of the various gases mentioned above. By way of example, an O₂ gas may be used. It is provided from the evaluation test that the hydrocarbons, i.e., carbons are removed from the resist film 12 as a result of supplying the O₂ gas to the wafer W in the vacuum atmosphere. When performing such a processing with the non-plasma O₂ gas, an apparatus or module configured in the same manner as the plasma processing module 7, except that no RF power supplies are provided and no plasma is formed in the processing vessel 71, may be prepared and used to perform the processing.

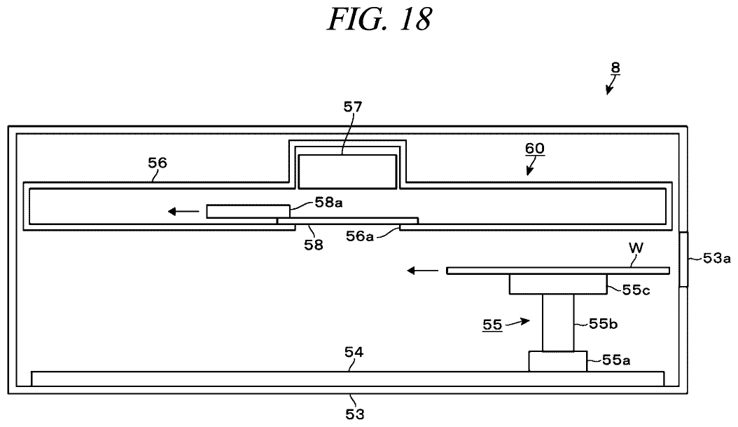

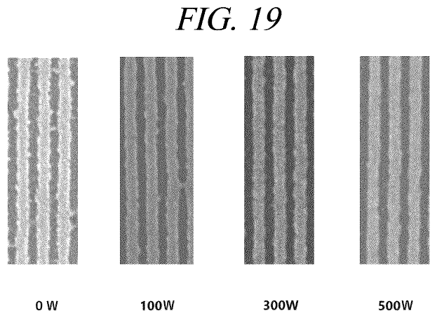

In addition, instead of performing the O₂ plasma processing in the process S7A (hereinafter sometimes referred to as O₂ ashing) in the second exemplary embodiment, the processing of reducing the concentration of the hydrocarbons in the resist pattern may be carried out by irradiating the resist pattern with ultraviolet rays (UV). A UV radiation apparatus 8, which is an example of a UV radiation apparatus configured to perform this processing, will be explained with reference to a longitudinal side view of FIG. 18. The UV radiation apparatus 8 has a rectangular housing 53, and a moving mechanism 54, a support 55, and a light source module 60 that are provided inside the housing 53. A transfer port 53a, which is an opening through which the wafer W is carried in and out, is provided in a sidewall of the housing 53. The moving mechanism 54 is provided on a bottom surface inside the housing 53, and the support 55 is mounted to the moving mechanism 54. The support 55 has a support base 55a fixed to the moving mechanism 54, a rotary member 55b extending vertically upwards from the support base 55a, and a disk-shaped placement table 55c mounted to an upper end of the rotary member 55b. The wafer W introduced through the transfer port 53a is placed on the placement table 55c. The placement table 55c attracts and holds the wafer W. The housing 53 is usually arranged so that the bottom surface on which the moving mechanism 54 is provided is horizontal, and the wafer W is held on the placement table 55c so that its main surface is horizontal.

The light source module 60 is located above the moving mechanism 54 and the support 55 inside the housing 53. The light source module 60 has a housing 56, and a light source 57 provided inside the housing 56. The light source 57 generates, for example, extreme ultraviolet (EUV) light as the UV used for exposure. The housing 56 has an opening 56a formed directly below the light source 57, and is also provided with a shutter 58 for opening and closing the opening 56a. The shutter 58 is moved between a closing position where it closes the opening 56a and an opening position where it opens the opening 56a by a shutter moving mechanism 58a provided inside the housing 56.

When the light source 57 is turned on and the shutter 58 is moved to the opening position to open the opening 56a, the support 55 is moved horizontally in the housing 53 by the moving mechanism 54, so that the entire resist film 12 of the wafer W is irradiated with the ultraviolet rays. In the meantime, the rotary member 55b is rotated, causing the wafer W to be rotated around its central axis.

Furthermore, the processing of reducing the concentration of the hydrocarbons in the resist pattern may be carried out by irradiating the resist film 12 with an oxygen ion beam. With this processing, the same effect as obtained when the ashing processing with the O₂ plasma in the process S7A is performed is expected. As a representative example of an apparatus configured to perform such a processing, an example of an ion implantation apparatus that performs an oxygen ion beam radiation processing will be briefly explained. The ion implantation apparatus has, for example, a housing, an oxygen gas supply mechanism configured to supply, for example, an oxygen gas as the oxidizing gas, and an ion generation mechanism configured to excite the supplied oxygen gas into plasma. The ion implantation apparatus may also be equipped with an accelerator, a focusing lens, and a deflector. The oxygen gas is excited into plasma by the ion generation mechanism, ions are extracted from the oxygen plasma and accelerated by the accelerator, the beam is narrowed by the focusing lens and scanned by the deflector to radiate oxygen ions toward the wafer W, and the oxygen ions are implanted into the resist film 12.

The apparatus that supplies the non-plasma O₂ gas, the UV radiation apparatus 8, and the oxygen ion implantation apparatus described above may be incorporated into the wafer processing system 2 as modules, or may be configured as separate apparatuses from the wafer processing system 2, or modules in those separate apparatuses. When provided as modules in the wafer processing system 2, the apparatus that supplies the non-plasma O₂ gas may be provided in place of at least one of the two plasma processing modules 7. The UV radiation apparatus 8 may also be provided in lieu of one of the resist film forming module 44, the heating module 46, and the inspection module 34. When the apparatus that supplies the non-plasma O₂ gas, the UV radiation apparatus 8, and the oxygen ion implantation apparatus are provided as separate apparatuses from the wafer processing system 2 or as modules inside those separate apparatuses, the wafer W stored in the carrier C may be transferred between those apparatuses and the wafer processing system 2.

The various types of the processing of reducing the concentration of the hydrocarbons in the resist pattern described above can be performed regardless of whether the underlying film 23 below the resist film 12 described in FIG. 16 is an organic film or an inorganic film.

In addition, when performing the hydrocarbon concentration reducing processing by supplying the non-plasma oxidizing gas, which is not excited into plasma, to the wafer W, the processes from the developing processing to the inert gas plasma processing can be performed in one and the same processing vessel 71, the same as in the case of performing the hydrocarbon concentration reducing processing by exposing the wafer W to the oxidizing gas excited into plasma. Specifically, the developing module 48 may be configured such that the gas supply mechanism 85 is also capable of supplying the oxidizing gas, and the developing processing, the supply of the oxidizing gas, and the inert gas plasma processing can be performed on the wafer W in this order in the process vessel 71 of the developing module 48.

Instead of the processing of exposing the resist film 12 to the plasma of the inert gas in the process S7 or S7B in the various exemplary embodiments described above, it is deemed that the same effect can be obtained by radiating or implanting ion beams generated from the inert gas into the resist film. Therefore, such an ion implantation processing may be performed, and the exemplary embodiments are not limited to exposing the resist film 12 to the plasma of the inert gas. An ion implantation apparatus configured to implant ions of the inert gas may be incorporated into the wafer processing system 2 as a module, or may be configured as a separate apparatus from the wafer processing system 2 or a module inside that separate apparatus, the same as the oxygen ion implantation apparatus.

A substrate processing method includes, for example, a process of placing a substrate having a resist film made of a metal oxide resist formed thereon in a processing vessel, and a process of forming plasma of an inert gas inside the processing vessel and exposing the resist film to the plasma.

For example, the resist film in the substrate processing method is developed to be given a pattern, and the inert gas may be a helium gas. For example, in such a case, the substrate processing method further includes a process of supplying a RF power of 1000 W or less to an electrode configured to form the plasma in order to form the plasma of the inert gas.

In addition, the resist film in the substrate processing method is, for example, a resist film before being subjected to the exposure for forming the pattern by the development, and in such a case, the substrate processing method includes, for example, a process of setting the vicinity of the substrate, on which the resist film is formed but which is yet to be subjected to the exposure, into the vacuum atmosphere or the inert gas atmosphere.

A substrate processing apparatus includes a processing vessel placing therein a substrate having a resist film made of a metal oxide resist formed thereon, a gas supply mechanism configured to supply an inert gas into the processing vessel, and a plasma forming mechanism configured to excite the inert gas supplied from the gas supply mechanism into plasma so that the resist film is exposed to the plasma of the inert gas.

For example, in this substrate processing apparatus, the resist film is provided with a pattern formed by being developed after being exposed, and the gas supply mechanism supplies an oxidizing gas and the inert gas into the processing vessel. The substrate processing apparatus includes a controller that controls the operations of the gas supply mechanism and the plasma forming mechanism so that the resist film is exposed to the plasma of the oxidizing gas and the plasma of the inert gas in this order.

For example, in the substrate processing apparatus, the resist film has been exposed to light, and the gas supply mechanism supplies a developing gas configured to develop the resist film and the inert gas into the processing vessel. The substrate processing apparatus includes a controller that controls the operation of the gas supply mechanism such that the gas supply mechanism supplies the developing gas and the inert gas into the processing vessel in this order.

For example, in the substrate processing apparatus, the resist film is provided with a pattern formed by being developed after being exposed. The substrate processing apparatus includes a film removing module configured to remove the resist film from the substrate, a resist film forming module configured to form the resist film, a developing module configured to develop the exposed resist film to form the pattern, an inspection module configured to acquire data for detecting an abnormality in the pattern, and a controller configured to determine presence or absence of the abnormality in the pattern based on the data. When it is determined that there is the abnormality in the pattern, the controller controls the operations of the film removing module, the resist film forming module, and the developing module so that the resist film is removed by the film removing module, the resist film is formed again by the resist film forming module on the substrate from which the previous resist film has been removed, and the newly formed resist film after being exposed is developed by the developing module so that the pattern is formed again.

Furthermore, in the various exemplary embodiments, the substrate as a processing target is not limited to the wafer, and a substrate for manufacturing a flat panel display, a mask substrate for manufacturing a mask for exposure, or the like may also be used. Thus, a rectangular substrate may also be processed. The above-described exemplary embodiments should be considered to be illustrative in all aspects and not anyway limiting. The above-described exemplary embodiments may be omitted, replaced and modified in various ways without departing from the scope and the spirit of appended claims.

Now, various evaluation tests conducted in relation to the technology of the present disclosure will be explained. In the evaluation tests, the plasma processing is performed on the resist pattern by using the plasma processing module 7 described in the exemplary embodiments. When performing the plasma processing using the He gas, the RF power of 100 MHz from the second RF power supply 87 is not supplied, and the output of the RF power of 13 MHz from the first RF power supply 86 is adjusted. That is, the first RF power supply 86 is used as the power supply configured to form the plasma of the inert gas.

### [Evaluation Test 1]

In this evaluation test, a change in the shape of the resist pattern due to variations in the RF power for the above-mentioned plasma formation is investigated for the processing in the first exemplary embodiment (PAB→exposure→PEB→development→HB→plasma processing). In this evaluation test, first, a wafer W on which identical resist patterns are formed through PAB to HB is divided into multiple chips, and nine bare wafers on which no resist film is formed are prepared. Then, the respective chips are placed one by one at central regions on surfaces of the respective bare wafers to prepare test substrates, and a plasma processing is then performed on the respective test substrates under different RF power conditions.

Plasma processing conditions other than the RF power are set to be the same between the substrates. Specifically, the pressure of the processing space 70 is set to 300 mTorr (40 Pa), the flow rate of the He gas supplied to the processing space 70 is set to 900 sccm, the temperature of the substrate during the plasma processing is set to 20° C., and the plasma formation time is set to 10 seconds. The RF power supplied from the first RF power supply 86 is changed for each substrate, and is set to 100 W, 200 W, 300 W, 500 W, 1000 W, 1500 W, 2000 W, and 3000 W, respectively. Further, as a comparative example, one of the test substrates prepared as described above is not subjected to the plasma processing. In the following explanation, the substrate of this comparative example may sometimes be identified as the one to which a RF power of 0 W is supplied. Images of the respective substrates after being subjected to the plasma processing and the substrate of the comparative example are obtained by using scanning electron microscope (SEM), and presence or absence of defects in the resist pattern, such as bridging and pinching, are checked, and LER is calculated.

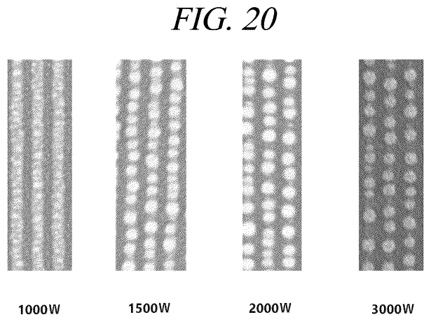

FIG. 19 and FIG. 20 are images showing test results of Evaluation Test 1, illustrating top surfaces of the resist films. In each image, the wall portion (protrusion) of the resist pattern appear with higher brightness than the opening (depression) of the resist pattern. FIG. 19 provides SEM images of the respective samples corresponding to the RF powers of 0 W to 500 W. The images of the samples corresponding to the RF powers of 200 W and 400 W are not shown because they are not significantly different from the images of the samples corresponding to the RF powers of 100 W and 300 W, respectively. FIG. 20 shows SEM images of the respective samples corresponding to the RF powers of 1000 W to 3000 W.

As for the substrate corresponding to the RF power of 0 W shown in FIG. 19, the roughness of the surface of the wall portion 16 is found to be high, and this roughness is found to cause a defect (so-called a bridge defect) that an unnecessary resist film remains between the wall portions 16. The LER of this substrate corresponding to the RF power of 0 W is observed to be 2.48 nm. In contrast, in the substrates corresponding to the RF powers of 100 W to 1000 W shown in FIG. 19 and FIG. 20, the roughness of their wall portions 16 is found to be significantly reduced, while suppressing the bridge formation. The LER values of the substrates corresponding to the RF powers of 100 W, 200 W, 300 W, 400 W, 500 W, and 1000 W are found to be 2.19, 2.17, 2.22, 1.99, 2.00, and 3.00, respectively. Thus, the LER values of the substrates corresponding to the RF powers of 100 W to 500 W are smaller than that of the substrate corresponding to the RF power of 0 W, and the LER value of the substrate corresponding to the RF power of 1000 W is larger than that of the substrate corresponding to the RF power of 0 W. However, in the image of the substrate corresponding to the RF power of 1000 W, the roughness is reduced so the bridge defect is suppressed, as compared to the image of the substrate corresponding to the RF power of 0 W. As can be seen from these results, in order to suppress the roughness of the resist pattern, it is desirable to set the RF power for plasma formation to 1000 W or less, and, more desirably, 500 W or less.

Furthermore, as can be seen from FIG. 20, the substrates supplied with the RF powers of 1500 W to 3000 W are found to have experienced the change in the wall portion of the resist pattern described in FIG. 15 of the fifth exemplary embodiment, as compared to the substrate supplied with the RF power of 0 W. That is, linear wall portions are broken down into circular wall portions. From the brightness on the images, it is found out that the wall portions are more clearly separated with a rise of the RF power in the range of 1500 W to 3000 W. As can be seen from these results of Evaluation Test 1, in order to change the resist pattern as described above in the fifth exemplary embodiment, it is desirable that the RF power for plasma formation is set to be higher than 1000 W, and, more desirably, to be equal to or higher than 1500 W.

### [Evaluation Test 2]

In this evaluation test, a resist pattern not subjected to the plasma processing (pattern without the plasma processing), which is a comparative example, is compared with a resist pattern subjected to a plasma processing (pattern with the plasma processing) of the first exemplary embodiment, which is an experimental example, to investigate the effect of the plasma processing of the first exemplary embodiment. The comparison is made in terms of critical dimension (CD) as the width of each resist pattern, LWR, and LER. This evaluation test is performed in the same manner as Evaluation Test 1, but since different samples are prepared separately, the values are slightly different. Further, in the plasma processing of the pattern of the experimental example using the inert gas, the RF power is set to 300 W.

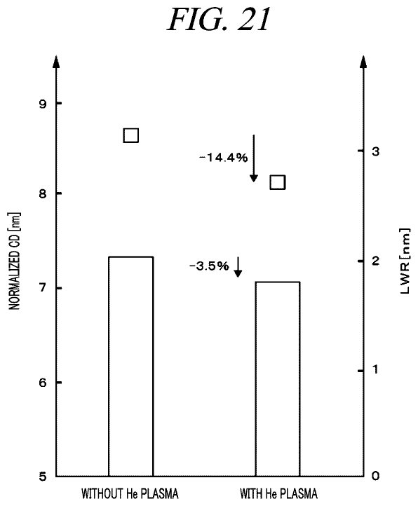

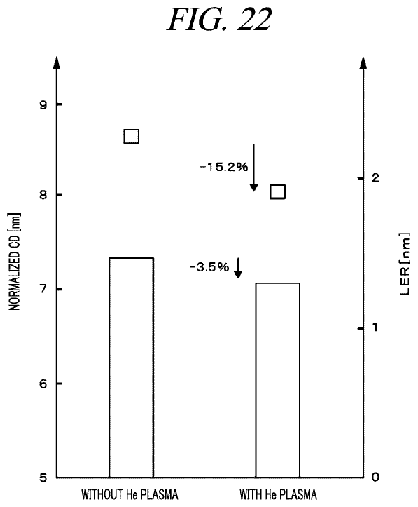

FIG. 21 and FIG. 22 are graphs showing test results of Evaluation Test 2. FIG. 21 shows CD and LWR values in respective resist patterns with and without the He plasma processing, and FIG. 22 is a graph showing CD and LER values in the respective resist patterns. In FIG. 21 and FIG. 22, CD is indicated by bar graphs, while LWR or LER is indicated by dots. The CD is a normalized value obtained by dividing a measurement value by a preset positive number. This CD represents a dimension corresponding to a width of a wall portion of the resist pattern, as distinguished from its space.

As shown in FIG. 21 and FIG. 22, when the CD of the pattern not subjected to the plasma processing (pattern of the comparative example) is defined as 100%, the CD of the resist pattern subjected to the plasma processing (pattern of the experimental example) is 3.5% smaller than the CD of the pattern without the plasma processing. Meanwhile, as shown in FIG. 21, when the LWR of the pattern without the plasm processing is defined as 100%, the LWR of the pattern with the plasma processing is 14.4% lower than the LWR of the pattern without the plasma processing. Also, as shown in FIG. 22, when the LER of the pattern without the plasma processing is defined as 100%, the LER of the pattern with the plasma processing is 15.2% lower than the LER of the pattern without the plasma processing.

In this way, the CD is slightly reduced by performing the plasma processing. That is, relatively large etching of the wall portion of the resist pattern due to the plasma processing is suppressed. Meanwhile, the LWR and LER are relatively significantly reduced, which is a desirable result. This result is considered to be due to, as described in the first exemplary embodiment, the breaking and the re-forming of the bonds between some of the Sn atoms 13 and the oxygen atoms 17, which lead to a highly uniform arrangement of the individual atoms, and to the use of the plasma formed from the relatively low-weighted He molecules, which results in suppression of pattern etching.

### [Evaluation Test 3]

In this evaluation test, patterns of the underlying film 11 etched using the resist pattern of the comparative example, which is not subjected to the plasma processing, and the resist pattern of the experimental example subjected to the plasma processing are investigated, and the properties of the respective resist patterns are compared. In Evaluation Test 3, as in Evaluation Tests 1 and 2, the resist pattern with the plasma processing is a pattern formed by performing the processes S1 to S7 in the processing flow of FIG. 1, and the resist pattern without the plasma processing is a pattern formed by performing only the processes S1 to S6, excluding the process S7.

While varying an exposure dose during the exposure in the process S3 for each wafer W, resist patterns of the experimental example having multiple CD values and resist patterns of the comparative example having multiple CD values are formed on the wafers W. Then, the respective wafers W are etched under the same conditions to transfer the respective resist patterns onto underlying films 11. CD values of patterns of the respective underlying films 11 etched in this way are measured. Here, the CD of the pattern of the underlying film 11 may be referred to as CD of after-etch-inspection (AEI) (hereinafter, referred to as AEI CD). This AEI CD, like the CD of the resist pattern, represents the width of the wall portion forming the pattern, distinguished from a space of the pattern. In this Evaluation Test 3, the individual CD values are normalized as in Evaluation Test 2.

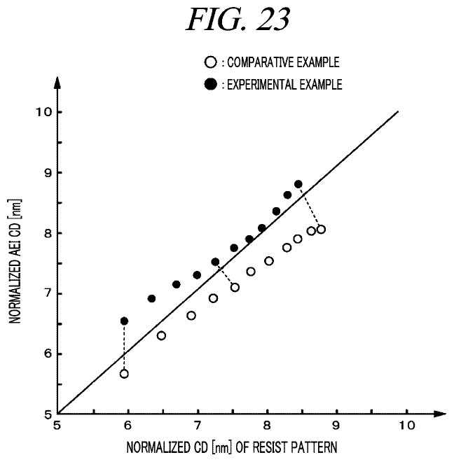

FIG. 23 is a graph showing the AEI CD with respect to the CD of the resist pattern for each of the comparative example and the experimental example. A solid line on the graph connects points where the CD of the resist pattern and the AEI CD are the same. In comparison of the AEI CD of the comparative example with the AEI CD of the experimental example from this graph, when the CD values of the resist pattern are the same or approximately the same, the AEI CD of the experimental example is larger. That is, the width of the wall portion of the underlying film 11 is larger in the experimental example. Therefore, the resist pattern of the experimental example is found to have higher resistance to the etching than the resist pattern of the comparative example because the opening width of the resist pattern between the wall portions is not enlarged when etching the underlying film 11 in the experimental example. This indicates that the resist film has been modified by the He plasma processing.

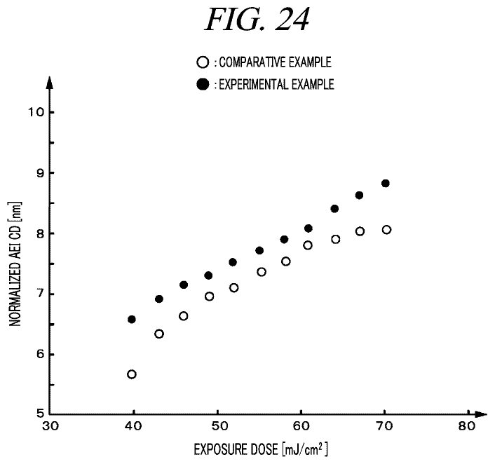

FIG. 24 is a graph showing the AEI CD with respect to the exposure dose for each of the comparative example and the experimental example. As can be seen from the plot representing the comparative example in the graph, when the exposure dose is low, the AEI CD is found to be relatively small for that exposure dose. That is, in the comparative example, there is a low correlation between the exposure dose and the AEI CD. Meanwhile, as can be seen from the plot representing the experimental example in the graph, when the exposure dose is low, the AEI CD is found to be larger than that of the comparative example. This indicates that there is a higher correlation between the exposure dose and the AEI CD in the experimental example than in the comparative example. Therefore, it is desirable to perform the He plasma processing as in the experimental example because it enables a control of the AEI CD over a wider range of exposure doses when controlling the AEI CD through the adjustment of the exposure dose.

### [Evaluation Test 4]

In this evaluation test, a processing of a comparative example and a processing of an experimental example are performed under the same conditions as in Evaluation Test 3. That is, the formation of the resist pattern with the plasma processing with the inert gas is performed following the processing flow of the first exemplary embodiment, and the formation of the resist pattern without the plasma processing is performed. In this Evaluation Test 4, however, the HB in the processing flow of the experimental example is performed after the plasma processing. Then, the number of defects such as bridging and pinching are counted and evaluated on various locations on the wafers W on which the resist patterns are respectively formed by the processing of the experimental example and the processing of the comparative example.

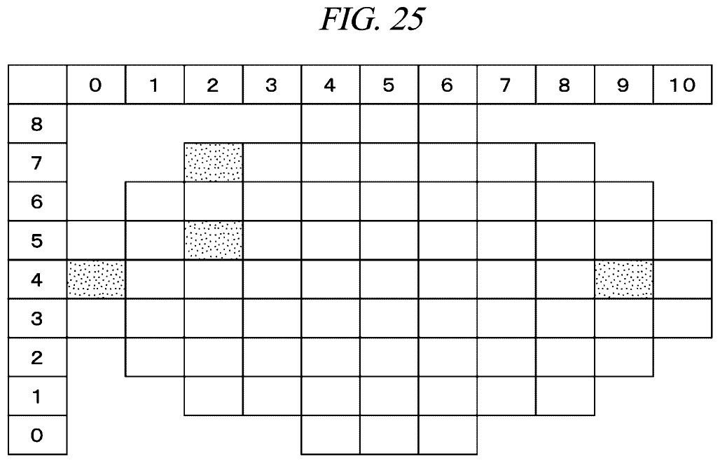

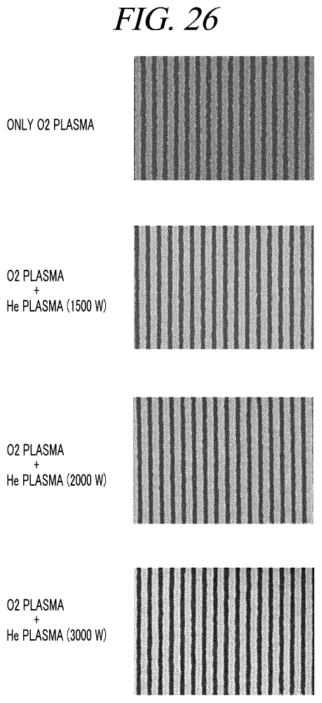

The counting of the number of the defects is carried out for individual division regions obtained by dividing a surface of each wafer W having a diameter of a 300 mm into a matrix form, as shown in FIG. 25. FIG. 25 is a diagram showing the number of defects in the division regions of the wafer W subjected to the processing of the experimental example. In the figure, the regions shown in white are where the number of defects is zero or approximately zero, and the dotted regions are where only a small number of defects are measured. In contrast, in the wafer W processed according to the comparative example, defects are observed in all of the divided regions, although a diagram showing the number of the defects is omitted. An average value of the defects in the entire surface of the wafer W and 3σ are found to be lower in the experimental example than in the comparative example. From this test result, it is confirmed that the plasma processing of the first exemplary embodiment can effectively suppress defects over a wide range of the surface of wafer W.

### [Evaluation Test 5]

In this evaluation test, a wafer W subjected to the processing of the second exemplary embodiment without HB is diced into chips in the same way as in Evaluation Test 1, and SEM images are obtained to evaluate presence or absence of defects and LER. Conditions for the O₂ plasma processing in the process S7A in the processing flow of FIG. 9 are as follows: the pressure in the processing space 70 is 10 mTorr (1.33 Pa), the RF power supplied from the second RF power supply 87 of 100 MHz is 500 W, the RF power supplied from the first RF power supply 86 of 13 MHz is 100 W, the flow rate of the O₂ gas supplied into the processing space 70 is 120 sccm, the temperature of the wafer W during the plasma formation is 20° C., and the plasma formation time is 5 seconds. Then, for each chip after being subjected to the O₂ plasma processing, the He plasma processing of the process S7 is performed while varying the RF power from the first RF power supply 86 to 1500 W, 2000 W, and 3000 W. The other conditions for the He plasma processing are the same as in Evaluation Test 1. Further, one of the chips after the O₂ plasma processing is not subjected to the He plasma processing as a comparative example.

FIG. 26 presents the SEM images showing the test results of the individual samples (chips) in Evaluation Test 5, illustrating top surfaces of resist patterns. According to the image of the sample of the comparative example on which only the O₂ plasma processing has been performed without the He plasma processing, the LER is found to be 2.36. According to the images of the samples for which the RF power for the He plasma processing is set to be 1500 W, 2000 W, and 3000 W, respectively, the breaking of the wall portions 16 of the resist patterns (See FIG. 20), which has occurred in the experimental example of Evaluation Test 1 due to DSA, has not occurred. This is deemed to be because, as explained in FIG. 11, the molecules 92 of the hydrocarbon compound are removed by the plasma of the O₂ gas, which suppresses, during the He plasma processing, the migration of the particles 93 of the oxidized Sn 15 explained in FIG. 10. When the RF power in the He plasma processing is 1500 W, 2000 W, and 3000 W, the LER is found to be 1.70, 1.76, and 1.59, respectively, which are lower than the LER values measured when the He plasma processing is not performed in this Evaluation Test 5 and the above-described Evaluation Test 1, so that desirable results are achieved.

In the first exemplary embodiment, the RF power supplied in the He plasma processing is set to have an RF power higher than 1000 W to cause DSA, but from Evaluation Test 5, it is found that when the O₂ plasma processing is performed, DSA can be suppressed even if the RF power is set to a value higher than 1000 W. That is, in order to reduce the roughness of the resist pattern without causing DSA, it is desirable to set the RF power to 1000 W or more. Furthermore, from the images obtained in Evaluation Test 5, it is proved that the desirable results are acquired with the setting of the RF power to 1500 W or more. Thus, it is more desirable to set the RF power to 1500 W or more.

### [Evaluation Test 6]

In this evaluation test, etching is performed by using the resist pattern processed according to the fifth exemplary embodiment, and an SEM image of the resist pattern before being etched and an SEM image of the underlying film 11 of the wafer W after being etched are obtained. Then, the effectiveness of the etching processing using the resist pattern is evaluated.

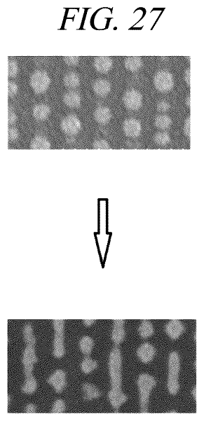

FIG. 27 presents the SEM image of the resist pattern before being etched and the SEM image of the underlying film 11 of the wafer W after being etched. When viewed from the top, imaging positions are not the same and do not correspond to each other. As can be seen from these images, multiple cylindrical patterns are formed on the underlying film 11 after being etched, and it is proved that the processing of the fifth exemplary embodiment is effective when the formation of such a pattern is required.

### [Evaluation Test 7]

Evaluation Test 7 is conducted by using the plasma processing module 7 to examine desirable processing conditions for suppressing the pattern collapse described in FIG. 17 for the O₂ ashing in the process S7A of the second exemplary embodiment. In this Evaluation Test 7, a processing is performed under different conditions for wafers each having a developed resist film 12 on an organic film, and states of the organic films and the resist patterns are investigated. To elaborate, the processing is performed by varying, between the wafers W, a combination of the pressure in the processing vessel 71, the power (HF power) supplied from the second RF power supply 87 (at 100 MHz frequency), the flow rate of the O₂ gas supplied into the processing vessel 71, and the flow rate of the gas (Ar gas or He gas) supplied into the processing vessel 71 together with the O₂ gas. Tests with different combinations of these processing parameters are referred to as Evaluation Tests 7-1 to 7-5. The processing conditions for Evaluation Tests 7-1 to 7-5 are as shown in Table 1 below. In Evaluation Test 7, no power (LF power) is supplied from the first RF power supply 86 (at 13 MHz frequency). The processing time (plasma formation time) is set to 5 seconds. Further, as Comparative Example 7, for a wafer W having a developed resist film 12 on an organic film and not subjected to the plasma processing, states of the organic film and the resist pattern are also investigated by acquiring SEM images thereof, in the same way as for the wafers W in Evaluation Tests 7-1 to 7-5.

TABLE 1

| | Pressure in | | | | |
|---|---|---|---|---|---|
| | Processing | HF | | | |
| Evaluation | Vessel | Power | O₂ | Ar | He |
| Test | (mTorr) | (W) | (sccm) | (sccm) | (sccm) |
| 7-1 | 10 | 200 | 20 | 200 | 0 |
| 7-2 | 10 | 200 | 20 | 0 | 200 |
| 7-3 | 10 | 200 | 20 | 0 | 100 |
| 7-4 | 10 | 200 | 20 | 0 | 100 |
| 7-5 | 100 | 100 | 120 | 0 | 0 |

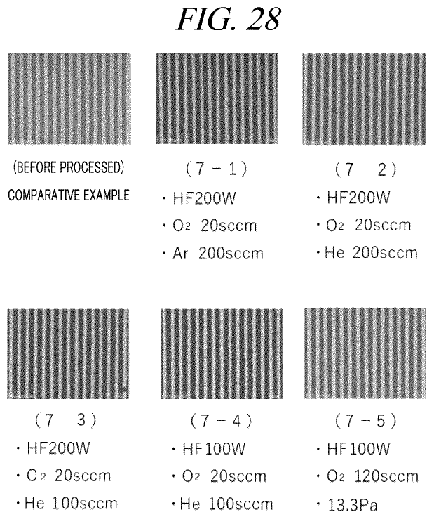

As compared to the wafer W of Comparative Example 7, the organic films of the wafers W in Evaluation Tests 7-1 to 7-4 are etched relatively significantly. However, the etching of the organic film of the wafer W in Evaluation Test 7-5 is found to be relatively suppressed, which is a desirable result. FIG. 28 provides SEM images of top surfaces of the wafers after the tests of Comparative Example 7 and Evaluation Tests 7-1 to 7-5. The pattern of Evaluation Test 7-5, like the pattern of Comparative Example 7, does not show pinching, and is in a desirable state.

Therefore, it is found out from the results of Evaluation Test 7 that the processing can be performed appropriately by forming plasma without supplying a gas other than the O₂ gas. The results of Evaluation Test 7 also show that it is desirable to set the internal pressure of the processing vessel 71 to be higher than 10 mTorr and to be equal to or higher than 100 mTorr (13.3 Pa). As for the reason why the etching of the underlying organic film is suppressed by setting the pressure in the processing vessel 71 to a relatively high level, the amount of molecules in a gas remaining in the processing vessel 71 is relatively large due to such a high pressure, and active species generated from the O₂ gas by plasma excitation collide with these molecules and active species excited from these molecules. That is, the active species generated from the O₂ gas are unlikely to reach the organic film due to the collision.

### [Evaluation Test 8]

In Evaluation Test 8, the range of the power (HF) supplied from the second high frequency power supply for O₂ ashing that can reduce the damage to the organic film of the wafer W observed in Evaluation Test 7 is investigated. In this evaluation test, the setting of Evaluation Test 7-5 that has produced the favorable results in Evaluation Test 7 is used: the power (LF power) from the first RF power supply 86 is 0 W, the processing pressure is 13.3 Pa (100 mTorr), and the flow rate of the O₂ gas supplied is 120 sccm. Then, the processing is performed for a processing time of 5 seconds, while varying the power (HF power) from the second RF power supply 87 (at 100 MHz frequency) for wafers W. In this evaluation test, the power of the second RF power supply 87 is set to 300 W, 75 W, 100 W, 200 W, and 500 W.

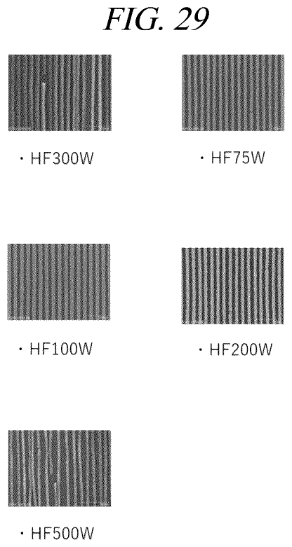

FIG. 29 shows SEM images of top surfaces of the wafers after being subjected to each processing in Evaluation Test 8. When the O₂ ashing is performed by setting the power of the second RF power supply 87 to 300 W or 500 W, the organic film between the patterns is significantly etched, resulting in pattern collapse and disturbance in pattern arrangement. When the O₂ ashing is performed by setting the power of the second RF power supply 87 to 75 W, 100 W, or 200 W, the pattern arrangement of the resist film is maintained, and the removal of the organic film between the patterns is suppressed. From a non-illustrated longitudinal cross sectional SEM image of the wafer W (not shown), the etched amount of the organic film is found to be reduced as the HF power is lowered. That is, the setting of 75 W shows the most favorable result. From the above, it is found out that the power supplied to the electrode for plasma formation by the second RF power supply 87 is desirably 200 W or less, and more desirably as small as possible. However, although not shown here, when the power of the second RF power supply 87 is set to 50 W, no plasma is ignited and no processing takes place. In view of this, it is desirable to set the power of the second RF power supply 87 to be higher than, e.g., 50 W.

### [Evaluation Test 9]

In Evaluation Test 9, a test is conducted to verify the effect of the O₂ ashing confirmed in the above-described evaluation tests. As Evaluation Tests 9-1 to 9-4, the O₂ ashing is performed on multiple wafers under the following conditions: the pressure in the processing vessel 71 is 100 mTorr (13.3 Pa), the power supplied from the first RF power supply 86 is 0 W, the power supplied from the second RF power supply 87 is 100 W, the flow rate of the O₂ gas supplied into the processing vessel is 120 sccm, and the processing time is 5 seconds. Further, as Evaluation Tests 9-1 to 9-4, after the O₂ ashing, the He plasma processing as described in the process S7 of the exemplary embodiment is performed. This He plasma processing is performed under the following conditions: the processing time is 10 seconds, the pressure in the processing vessel 71 is 40,000 Pa (300 Torr), the flow rate of the He gas supplied into the processing vessel 71 was 900 sccm, and the power (HF power) supplied from the second RF power supply 87 is 0 W. The power (LF power) supplied from the first RF power supply 86 is set to be different between Evaluation Tests 9-1, 9-2, 9-3, and 9-4, that is, set to 3000 W, 1500 W, 1000 W, and 500 W, respectively. Then, SEM images of the wafers W being subjected to the He plasma processing are acquired.

Furthermore, as Evaluation Test 9-5, O₂ the ashing is performed on a wafer W in the same manner as in Evaluation Tests 9-1 to 9-4, and an SEM image of this wafer W is obtained. Therefore, in Evaluation Test 9-5, the wafer W is not exposed to plasma of the He gas. Furthermore, as Evaluation Test 9-6, a wafer W is exposed to plasma of the He gas formed under the same conditions as Evaluation Test 9-1. Thus, the plasma of the He gas is formed by setting the power from the first RF power supply 86 to 3000 W. Then, an SEM image of the wafer W after being processed is acquired. Thus, in Evaluation Test 9-6, the O₂ ashing is not performed. Furthermore, as Comparative Example 9, an SEM image of a wafer on which a resist pattern is formed under the same conditions as Evaluation Tests 9-1 to 9-6 and which is not subjected to a plasma processing is also acquired.

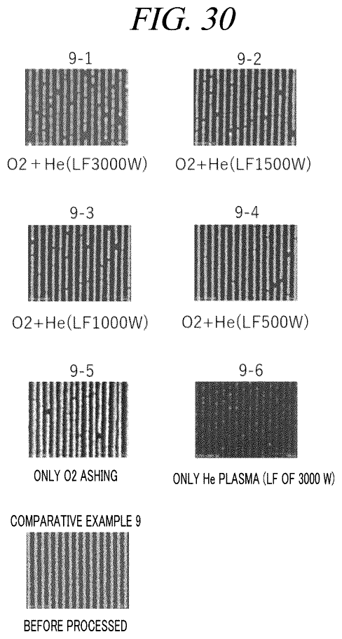

FIG. 30 shows the SEM images of top surfaces of the wafers in Evaluation tests 9-1 to 9-6 and Comparative Example 9. In Evaluation Test 9-6, in which the He plasma processing is performed without performing the O₂ ashing, the resist film is etched relatively heavily, resulting in the loss of the resist pattern. However, in Evaluation Tests 9-1 to 9-4, in which the plasma processing is performed after the O₂ ashing is carried out, the resist patterns remain, although pinching is observed as compared to Comparative Example 9. This pinching becomes more conspicuous as the power from the first RF power supply 86 increases. In Evaluation Test 9-5, where only O₂ ashing is performed, the resist pattern remains. From these results, it is found that the O₂ ashing makes the resist pattern solid, increasing the resistance of the resist pattern against the He plasma processing. This increase in the resistance is presumed to be due to the promotion of the formation of bonds between Sn atoms via oxygen, which is caused by the release of hydrocarbon ligands from the Sn atoms, as described in the above exemplary embodiment.

### [Evaluation Test 10]

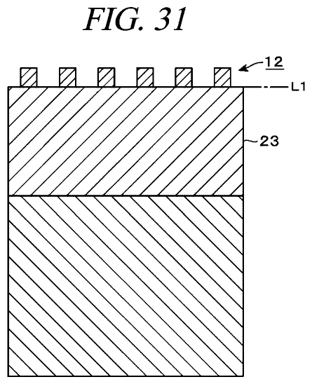

In Evaluation Test 10, the processing vessel is set into the vacuum atmosphere, and the O₂ gas is supplied to each wafer W stored in the processing vessel without plasma formation. SEM images of the wafer W before and after this gas supply are acquired, and FIG. 31 is a schematic diagram showing an image of a lateral side of the wafer W before the gas supply. The wafer W has a resist pattern formed on an underlying film 23 composed of an amorphous carbon film. Specifically, as the gas processing, the supply of the O₂ gas is performed for 5 seconds under the vacuum atmosphere. The pressure in the processing vessel is set to 13.3 Pa, which is a suitable condition for O₂ ashing, and the wafers W are processed under different O₂ gas concentrations and O₂ gas flow rates. Although it is stated here that the O₂ gas is supplied to the wafers W in this Evaluation Test 10, a gas not containing the O₂ gas is supplied to some of the wafers W for comparison.

For the purpose of evaluating the O₂ gas concentration, the flow rates of the O₂ gas and an N₂ gas supplied into the processing vessel are varied to adjust the O₂ gas concentration within the processing vessel. As specific conditions, the flow rates of the O₂ gas and the N₂ gas are adjusted to set the O₂ gas concentration to 0% (0 sccm of O₂ gas and 120 sccm of N₂ gas), 2% (2.4 sccm of O₂ gas and 117.6 sccm of N₂ gas), 12.5% (15 sccm of O₂ gas and 105 sccm of N₂ gas), 25% (30 sccm of O₂ gas and 90 sccm of N₂ gas), 50% (60 sccm of O₂ gas and 60 sccm of N₂ gas), and 100% (120 sccm of O₂ gas, 0 sccm of N₂ gas). Further, only the O₂ gas is supplied into the processing vessel, and the flow rate of this O₂ gas is varied for each wafer W to evaluate the flow rate of the O₂ gas. The flow rate of this O₂ gas is set to 60 sccm, 90 sccm, 120 sccm, and 180 sccm. In this evaluation of the flow rate, only when the O₂ gas is set to 60 sccm, the pressure in the processing vessel is set to 70 mTorr to 80 mTorr, and the processing time is set to 1 minute as the supply flow rate of the gas is relatively small.

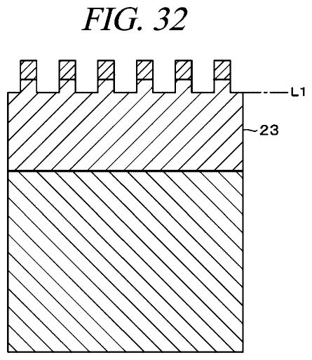

FIG. 32 is a schematic diagram showing an SEM image of the lateral sides of some wafers W. As shown in the figure, in some wafers W, the thickness of the underlying film 23 after being subjected to the processing is found to be reduced as compared to the thickness before the processing, and a downward displacement of a top surface position L1 of the underlying film 23 is observed. The underlying film 23 is composed of carbon (amorphous carbon) as stated above, so if a reduction in the thickness of this underlying film 23 is found, it is presumed that hydrocarbons in the resist film 12 have also been reduced.

As for evaluation results of the O₂ gas concentrations, when the O₂ gas concentration is 0% (when the N₂ gas is supplied without supplying the O₂ gas) and 2%, no displacement in the top surface position L1 is observed. In the processing under the high O₂ gas concentration of 12.5% or more, a downward displacement in the top surface position L1 is confirmed. Further, with an increase of the O₂ gas concentration, the downward displacement is found to increase. In view of this, it is estimated that the effect of reducing the hydrocarbons in the resist film 12 can be obtained when the O₂ gas concentration is 12.5% or more, and the effect of removing the hydrocarbons in the resist film 12 can be increased by increasing the O₂ gas concentration.

In addition, it is also confirmed that when air (i.e., a gas with an O₂ gas concentration of 20%) is supplied to the wafer W shown in FIG. 31 under an atmospheric pressure, no reduction in the thickness of the underlying film 23 has taken place. Thus, it is proved from this test result that, in order to obtain the effect of reducing the hydrocarbons in the resist film 12, it is effective to set the processing vessel in which the wafer W is placed into a vacuum atmosphere, at least when the O₂ gas concentration is 20% or less.

As for evaluation results of the supply flow rates of the O₂ gas, a downward displacement in the top surface position L1 is observed under each flow rate condition, and the downward displacement is found to increase with an increase of the flow rate of the O₂ gas. From this result, it is estimated that the same effect as the O₂ ashing processing can be obtained by supplying the non-plasma O₂ gas instead of performing the O₂ ashing processing, as described above.

According to the exemplary embodiment, it is possible to form the required pattern in the metal oxide resist.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing method, comprising:
performing, on a substrate having a resist film formed thereon, a reduction processing of reducing hydrocarbons contained in the resist film, the resist film including a metal oxide resist, exposed to light, and developed to have a pattern; and
performing a processing of reducing roughness of the resist film after being subjected to the reduction processing.

2. The substrate processing method of claim 1,
wherein the reduction processing is at least one of:
placing the substrate in a processing vessel and exposing the resist film of the substrate to a plasma by exciting an oxidizing gas;
exposing the resist film of the substrate to the oxidizing gas that is not excited into the plasma;
irradiating the resist film with an ultraviolet ray; and
irradiating the resist film with an ion beam of ions generated from the oxidizing gas.

3. The substrate processing method of claim 2,
wherein the resist film is provided on an underlying film on the substrate, the underlying film including carbon, and
the reduction processing is a processing of exposing the resist film of the substrate, which is placed in the processing vessel set to a pressure of 13.3 Pa or higher, to the plasma formed by exciting the oxidizing gas.

4. The substrate processing method of claim 2,
wherein the resist film is provided on an underlying film on the substrate, the underlying film including carbon, and
the reduction processing is a processing of exposing the resist film of the substrate, which is placed in the processing vessel, to the plasma formed by exciting the oxidizing gas, and the reduction processing comprises supplying a radio frequency (RF) power of 200 W or less to an electrode to form the plasma from the oxidizing gas.

5. The substrate processing method of claim 2,
wherein the reduction processing includes supplying the oxidizing gas that is not excited into plasma to the resist film of the substrate placed in the processing vessel in which a vacuum atmosphere is created.

6. The substrate processing method of claim 2,
wherein the oxidizing gas includes an oxygen gas.

7. The substrate processing method of claim 1,
wherein the processing of reducing the roughness is at least one of:
placing the substrate in a processing vessel and exposing the resist film of the substrate to a plasma generated by exciting an inert gas; and
irradiating the resist film with an ion beam of ions generated from the inert gas.

8. The substrate processing method of claim 7,
wherein the inert gas includes a helium gas.

9. The substrate processing method of claim 8,
wherein the processing of reducing the roughness includes exposing the resist film of the substrate placed in the processing vessel to the plasma generated by exciting the helium gas, and supplying a radio frequency (RF) power of 1000 W or more to an electrode for plasma formation to form the plasma from the helium gas.

10. The substrate processing method of claim 1, further comprising:
determining presence or absence of an abnormality in the pattern;
removing the resist film from the substrate in response to determining that there is the abnormality in the pattern; and
forming another resist pattern on the substrate after removal of the resist film by forming, exposing and developing another resist film on the substrate.

11. A substrate processing method, comprising:
placing, in a processing vessel, a substrate including a resist film formed thereon, the resist film including a metal oxide resist, exposed to light, and developed to have a pattern;
supplying an inert gas into the processing vessel; and
supplying a radio frequency power of 1000 W or higher to an electrode for plasma formation, and forming plasma from the inert gas to break down the pattern and modify the pattern.

12. The substrate processing method of claim 11, further comprising:
etching an underlying film formed under the resist film on the substrate, using the resist film using the pattern, after breaking down and modifying, as a mask.

13. A substrate processing apparatus, comprising:
a first processor that performs, on a substrate having a resist film formed thereon, a reduction processing to reduce hydrocarbons contained in the resist film, the resist film including a metal oxide resist, exposed to light, and developed to have a pattern; and
a second processor that performs a processing to reduce roughness of the resist film after being subjected to the reduction processing.

14. The substrate processing apparatus of claim 13,
wherein the reduction processing is at least one that:
places the substrate in a processing vessel and exposes the resist film of the substrate to a plasma generated through excitation of an oxidizing gas;
exposes the resist film of the substrate to the oxidizing gas that is not excited into the plasma;
irradiates the resist film with an ultraviolet ray; and
irradiates the resist film with an ion beam of ions generated from the oxidizing gas.

15. The substrate processing apparatus of claim 14,
wherein, in the reduction processing, the resist film of the substrate is exposed to the plasma formed through excitation of the oxidizing gas,
in the processing of reducing the roughness, the resist film of the substrate is exposed to a plasma formed through excitation of an inert gas,
the first processor and the second processor comprise:
a gas supply mechanism that supplies the oxidizing gas and the inert gas into the processing vessel; and
a plasma forming mechanism that excites each gas supplied from the gas supply mechanism into the plasma, and
the substrate processing apparatus further comprises a controller to control operations of the gas supply mechanism and the plasma forming mechanism such that the resist film is exposed to the plasma of the oxidizing gas before the plasma of the inert gas.

16. The substrate processing apparatus of claim 15,
wherein the gas supply mechanism supplies a developing gas to develop the resist film, an oxygen gas, and the inert gas into the processing vessel, and
the controller controls the gas supply mechanism to supply the developing gas before the oxygen gas, and the oxygen gas before the inert gas into the processing vessel.

17. The substrate processing apparatus of claim 16,
wherein the inert gas includes helium.

18. The substrate processing apparatus of claim 16, wherein the oxygen gas is the oxidizing gas.

19. The substrate processing apparatus of claim 13, further comprising:
a film remover that removes the resist film from the substrate;
a resist film former that forms the resist film;
a developer that develops the resist film after being exposed to form a pattern;
an inspector that acquires data to detect an abnormality in the pattern; and
a controller that determines presence or absence of the abnormality in the pattern based on the data,
wherein when it is determined that there is the abnormality in the pattern, the controller controls operations of the film remover, the resist film former, and the developer such that the film remover removes the resist film, the resist film former forms another resist film on the substrate, and the developer develops the another resist film after being exposed to re-form the pattern.

20. The substrate processing apparatus of claim 19, wherein the re-formed pattern is used as a mask to etch an underlying film formed under the resist film on the substrate.
